(19) United States
(12) Patent Application Publication
(10) Pub. No.: US 2024/0345475 A1
(43) Pub. Date: Oct. 17, 2024

(54) PREPARING FEATURES ON A SUBSTRATE USING NANO-IMPRINT LITHOGRAPHY

(71) Applicant: Illumina, Inc., San Diego, CA (US)

(72) Inventors: Krishnarjun Sarkar, San Diego, CA (US); Sahngki Hong, San Diego, CA (US); Weixian Xi, San Diego, CA (US); Brandon Wenning, San Diego, CA (US); Lewis Kraft, San Diego, CA (US); Jeffrey Fisher, San Diego, CA (US); Wayne George, Haverhill (GB); Brian Mather, San Diego, CA (US)

(73) Assignee: Illumina, Inc., San Diego, CA (US)

(21) Appl. No.: 18/633,865

(22) Filed: Apr. 12, 2024

Related U.S. Application Data
(60) Provisional application No. 63/496,355, filed on Apr. 14, 2023.

(51) Int. Cl. G03F 7/00

(52) U.S. Cl. CPC G03F 7/0002

(57) ABSTRACT

In some examples, a method includes disposing a first hydrogel within a first recess of a substrate and over a pillar. The substrate may include a second recess in which the pillar is disposed, and a wall separating the first recess from the second recess. While the first hydrogel is disposed within the first recess, the pillar may be removed. After removing the pillar, a second hydrogel may be disposed within the second recess. Also provided herein are nonlimiting examples of manners in which recesses, walls, and patterned hydrogels may be formed.

### CROSS-REFERENCE TO RELATED APPLICATIONS

This application claims the benefit of U.S. Provisional Patent Application No. 63/496,355, filed on Apr. 14, 2023 and entitled “Preparing Features On a Substrate Using Nano-Imprint Lithography,” the entire contents of which are incorporated by reference herein.

### FIELD

This application generally relates preparing features on a substrate.

### BACKGROUND

Cluster amplification is an approach to amplifying polynucleotides, for example for use in genetic sequencing. Target polynucleotides are captured by primers (e.g., P5 and P7 primers) coupled to a substrate surface in a flowcell, and form “seeds” at random locations on the surface. Cycles of amplification are performed to form clusters on the surface around each seed. The clusters include copies, and complementary copies, of the seed polynucleotides. In some circumstances, the substrate is patterned so as to define regions that bound different clusters, such as wells that may be filled with respective clusters. These wells may be referred to as “recesses.”

### SUMMARY

Examples provided herein are related to preparing features on a substrate using nano-imprint lithography.

Some examples herein provide a method that includes disposing a first hydrogel within a first recess of a substrate and over a pillar. The substrate may include a second recess in which the pillar is disposed, and a wall separating the first recess from the second recess. The method may include, while the first hydrogel is disposed within the first recess, removing the pillar. The method may include, after removing the pillar, disposing a second hydrogel within the second recess.

In some examples, the wall separates the first hydrogel from the second hydrogel.

In some examples, the first hydrogel is coupled to a first set of capture primers, and the second hydrogel is coupled to a second set of capture primers. In some examples, capture primers of the first set are of a different type than capture primers of the second set. In some examples, the first set of capture primers includes seeding primers. In some examples, the second set of capture primers includes amplification primers. In some examples, the first set of capture primers includes a first set of amplification primers. In some examples, the second set of capture primers includes a second set of amplification primers.

In some examples, the method includes coupling the first hydrogel to the first set of capture primers after removing the pillar from the recess and before disposing the second hydrogel within the first portion of the second region of the recess. In some examples, the second hydrogel is coupled to the second set of capture primers after the second hydrogel is disposed within the first portion of the second region of the recess.

In some examples, removing the pillar from the recess includes a liftoff operation.

In some examples, the first hydrogel is disposed on sidewalls of the first region of the recess, the sidewalls being formed at least by the first layer and the wall.

In some examples, the second hydrogel is disposed on sidewalls within the first portion of the second region of the recess, the sidewalls being formed at least by the first layer and the wall.

Some examples herein provide a method of patterning a substrate including a first layer, a mask layer disposed on the first layer, and second layer disposed on the mask layer. The method may include forming a recess in the second layer of substrate. The recess may include a first region and a second region, a lower surface of the first region being deeper within the second layer than a lower surface of the second region. The method may include using a first etching operation to extend the first region of the recess through the mask layer and into the first layer such that the lower surface of the first region is located within the first layer, and the lower surface of the second region of the recess is substantially located at the mask layer. The method may include forming a first pillar of photoresist within the recess. The first pillar may have a first region substantially filling the first region of the recess, and a second region partially extending into the second region of the recess. The method may include using a second etching operation to extend a first portion of the second region of the recess through the mask layer and into the first layer such that a lower surface of the first portion of the second region of the recess is located within the first layer. The first region of the first pillar may inhibit etching of the first region of the recess. The second region of the first pillar may inhibit etching of a second portion of the second region of the recess so as to form a wall located within the first layer and between the first region of the recess and the first portion of the second region of the recess.

In some examples, the recess is formed in the second layer of the substrate using nano-imprint lithography (NIL).

In some examples, the first etching operation includes a first process that removes a portion of the second layer, a second process that removes a portion of the mask layer, and a third process that removes a portion of the first layer.

In some examples, the first, second, and third processes include respective dry etch operations.

In some examples, the second etching operation includes a first process that removes a portion of the mask layer, and a second process that removes a portion of the first layer.

In some examples, the first, second, and third processes include respective dry etch operations.

In some examples, forming the first pillar of photoresist includes: depositing a photoresist precursor at least within the recess; exposing the photoresist precursor in a region corresponding to the first region of the recess and the second portion of the second region of the recess; and removing unexposed photoresist precursor. In some examples, the photoresist precursor is exposed through the first layer and through an aperture that the first etching operation forms through the mask layer. In some examples, the mask layer inhibits any exposure of the photoresist precursor in a region corresponding to at least the first portion of the second region of the recess. In some examples, the mask layer inhibits direct exposure of the photoresist precursor in a region corresponding to the second portion of the second region of the recess. In some examples, the photoresist precursor in the region corresponding to the second portion of the second region of the recess is exposed via overexposure through the aperture in the mask.

In some examples, the first and second materials respectively include a resin.

In some examples, the mask includes aluminum, copper, chromium, or gold.

In some examples, the wall has a thickness of about 20 nm to about 400 nm between the first region of the recess and the first portion of the second region of the recess. In some examples, the wall has a thickness of about 40 nm to about 300 nm between the first region of the recess and the first portion of the second region of the recess. In some examples, the wall has a thickness of about 100 nm to about 200 nm between the first region of the recess and the first portion of the second region of the recess.

In some examples, the method further includes removing the pillar. In some examples, removing the pillar includes a liftoff operation.

In some examples, the first etching operation undercuts a portion of the mask layer; and a third region of the first pillar extends into the undercut portion of the mask layer.

In some examples, during the second etching operation, the third portion of the first pillar inhibits etching of a portion of the first layer adjacent to the first recess.

In some examples, the method further includes, after the second etching operation, forming a second pillar of photoresist over the first portion of the second region of the recess. In some examples, the method further includes a third etching operation that partially removes the first and second pillars of photoresist and exposes the portion of the first layer adjacent to the first recess.

In some examples, the method further includes disposing a material on the exposed portion of the first layer adjacent to the first recess. In some examples, the material includes a hydrogel. In some examples, the hydrogel is coupled to capture primers.

In some examples, the method further includes, after the second etching operation, forming a second pillar of photoresist over the first portion of the second region of the recess. In some examples, the method further includes a third etching operation that partially removes the first and second pillars of photoresist and exposes portions of the first layer respectively adjacent to the first and second recesses. In some examples, the method further includes disposing a material on the exposed portions of the first layer respectively adjacent to the first and second recesses. In some examples, the material includes a hydrogel. In some examples, the hydrogel is coupled to capture primers.

In some examples, the third etching operation further exposes a portion of the wall. In some examples, the method further includes disposing a material on the exposed portion of the wall. In some examples, the material includes a hydrogel. In some examples, the hydrogel is coupled to capture primers.

Some examples herein provide a method that includes disposing a first hydrogel within a recess of a substrate. The method may include disposing a pillar over the first hydrogel within the recess of the substrate. The method may include disposing a second hydrogel over the pillar and over a portion of the substrate. The method may include removing the pillar.

In some examples, the substrate includes a resin in which the recess is formed.

In some examples, the recess is formed using nano-imprint lithography.

In some examples, the recess is symmetrical.

In some examples, the recess includes a first region having a lower surface which is deeper within the substrate than a lower surface of a second region.

In some examples, the pillar includes photoresist.

In some examples, the pillar is removed using a liftoff operation.

Some examples herein provide a method that includes disposing a first hydrogel on a first region of a wall. The method may include disposing a photoresist on the first hydrogel and on a second region of the wall. The method may include disposing a second hydrogel on the photoresist and on a third region of the wall. The method may include removing the photoresist to leave a portion of the first hydrogel coupled to the first region of the wall and to leave a portion of the second hydrogel coupled to the third region of the wall and at a spaced distance from the portion of the first hydrogel.

In some examples, the photoresist is removed using a liftoff operation.

In some examples, the method further includes forming the wall using nano-imprint lithography.

Some examples herein provide a method that includes forming first and second concentric annular apertures through a mask layer disposed on a substrate. The method may include etching the substrate through the first and second concentric annular apertures to form first and second recesses within the substrate.

In some examples, the method further includes forming a central aperture through the mask layer; and etching the substrate through the central aperture to form a third recess within the substrate. In some examples, the central aperture is formed using operations that include forming a recess in a second layer disposed over the mask layer, and then etching the second layer to extend the recess through the mask layer. In some examples, the recess is formed in the second layer using nano-imprint lithography.

In some examples, the first annular aperture is formed using operations that include forming a first pillar which partially covers the mask layer and partially exposes the mask layer, and etching the exposed portion of the mask layer. In some examples, the first pillar is formed using operations that include disposing a photoresist precursor over the mask layer, and overexposing the photoresist precursor through the central aperture.

In some examples, the second annular aperture is formed using operations that include forming second and third pillars which partially cover the mask layer and partially exposes the mask layer, and etching the exposed portion of the mask layer.

It is to be understood that any respective features/examples of each of the aspects of the disclosure as described herein may be implemented together in any appropriate combination, and that any features/examples from any one or more of these aspects may be implemented together with any of the features of the other aspect(s) as described herein in any appropriate combination to achieve the benefits as described herein.

### BRIEF DESCRIPTION OF DRAWINGS

FIGS. 1A-1G schematically illustrate example structures and operations for forming recesses in a substrate.

FIGS. 2A-2C schematically illustrate example structures and operations for disposing different hydrogels in respective recesses in a substrate.

FIGS. 3A-3I schematically illustrate additional example structures and operations for forming recesses in a substrate.

FIGS. 4A-4D schematically illustrate example structures and operations for disposing different hydrogels at different locations of a substrate.

FIGS. 5A-5M schematically illustrate additional example structures and operations for forming recesses in a substrate.

FIG. 6 schematically illustrates additional example structures and operations for disposing different hydrogels on different regions of a substrate.

FIG. 7 schematically illustrates example structures and operations for disposing different hydrogels on different regions of a substrate.

### DETAILED DESCRIPTION

Examples provided herein are related to preparing features on a substrate using nano-imprint lithography.

It can be useful to form features on substrates. For example, recesses in a substrate may be used in sequencing, e.g., of polynucleotides. Methods are provided herein for forming first and second recesses in a substrate that are separated from one another by a wall. Respective hydrogel(s) may be disposed within the respective recesses and/or on other location(s) of the substrate. Capture primers (e.g., seeding primers and/or amplification primers) may be coupled to the respective hydrogels, and used for seeding and/or amplification operations. In other examples, methods are provided herein for forming first and second hydrogels that are spaced apart from each other on a wall of a substrate. Capture primers (e.g., seeding primers and/or amplification primers) may be coupled to the respective hydrogels, and used for seeding and/or amplification operations.

First, some terms used herein will be briefly explained. Then, some example structures and example methods for preparing features on a substrate using nano-imprint lithography will be described.

### Terms

Unless defined otherwise, all technical and scientific terms used herein have the same meaning as is commonly understood by one of ordinary skill in the art. The use of the term “including” as well as other forms, such as “include,” “includes,” and “included,” is not limiting. The use of the term “having” as well as other forms, such as “have,” “has,” and “had,” is not limiting. As used in this specification, whether in a transitional phrase or in the body of the claim, the terms “comprise(s)” and “comprising” are to be interpreted as having an open-ended meaning. That is, the above terms are to be interpreted synonymously with the phrases “having at least” or “including at least.” For example, when used in the context of a process, the term “comprising” means that the process includes at least the recited steps, but may include additional steps. When used in the context of a compound, composition, or device, the term “comprising” means that the compound, composition, or device includes at least the recited features or components, but may also include additional features or components.

The terms “substantially,” “approximately,” and “about” used throughout this specification are used to describe and account for small fluctuations, such as due to variations in processing. For example, they may refer to less than or equal to ±10%, such as less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

As used herein, “hybridize” is intended to mean noncovalently associating a first polynucleotide to a second polynucleotide along the lengths of those polymers to form a double-stranded “duplex.” For instance, two DNA polynucleotide strands may associate through complementary base pairing. The strength of the association between the first and second polynucleotides increases with the complementarity between the sequences of nucleotides within those polynucleotides. The strength of hybridization between polynucleotides may be characterized by a temperature of melting (Tm) at which 50% of the duplexes have polynucleotide strands that disassociate from one another. Polynucleotides that are “partially” hybridized to one another means that they have sequences that are complementary to one another, but such sequences are hybridized with one another along only a portion of their lengths to form a partial duplex. Polynucleotides with an “inability” to hybridize include those which are physically separated from one another such that an insufficient number of their bases may contact one another in a manner so as to hybridize with one another.

As used herein, the term “nucleotide” is intended to mean a molecule that includes a sugar and at least one phosphate group, and in some examples also includes a nucleobase. A nucleotide that lacks a nucleobase may be referred to as “abasic.” Nucleotides include deoxyribonucleotides, modified deoxyribonucleotides, ribonucleotides, modified ribonucleotides, peptide nucleotides, modified peptide nucleotides, modified phosphate sugar backbone nucleotides, and mixtures thereof. Examples of nucleotides include adenosine monophosphate (AMP), adenosine diphosphate (ADP), adenosine triphosphate (ATP), thymidine monophosphate (TMP), thymidine diphosphate (TDP), thymidine triphosphate (TTP), cytidine monophosphate (CMP), cytidine diphosphate (CDP), cytidine triphosphate (CTP), guanosine monophosphate (GMP), guanosine diphosphate (GDP), guanosine triphosphate (GTP), uridine monophosphate (UMP), uridine diphosphate (UDP), uridine triphosphate (UTP), deoxyadenosine monophosphate (dAMP), deoxyadenosine diphosphate (dADP), deoxyadenosine triphosphate (dATP), deoxythymidine monophosphate (dTMP), deoxythymidine diphosphate (dTDP), deoxythymidine triphosphate (dTTP), deoxycytidine diphosphate (dCDP), deoxycytidine triphosphate (dCTP), deoxyguanosine monophosphate (dGMP), deoxyguanosine diphosphate (dGDP), deoxyguanosine triphosphate (dGTP), deoxyuridine monophosphate (dUMP), deoxyuridine diphosphate (dUDP), and deoxyuridine triphosphate (dUTP).

As used herein, the term “nucleotide” also is intended to encompass any nucleotide analogue which is a type of nucleotide that includes a modified nucleobase, sugar and/or phosphate moiety compared to naturally occurring nucleotides. Example modified nucleobases include inosine, xanthine, hypoxanthine, isocytosine, isoguanine, 2-aminopurine, 5-methylcytosine, 5-hydroxymethyl cytosine, 2-aminoadenine, 6-methyl adenine, 6-methyl guanine, 2-propyl guanine, 2-propyl adenine, 2-thiouracil, 2-thiothymine, 2-thiocytosine, 15-halouracil, 15-halocytosine, 5-propynyl uracil, 5-propynyl cytosine, 6-azo uracil, 6-azo cytosine, 6-azo thymine, 5-uracil, 4-thiouracil, 8-halo adenine or guanine, 8-amino adenine or guanine, 8-thiol adenine or guanine, 8-thioalkyl adenine or guanine, 8-hydroxyl adenine or guanine, 5-halo substituted uracil or cytosine, 7-methylguanine, 7-methyladenine, 8-azaguanine, 8-azaadenine, 7-deazaguanine, 7-deazaadenine, 3-deazaguanine, 3-deazaadenine or the like. As is known in the art, certain nucleotide analogues cannot become incorporated into a polynucleotide, for example, nucleotide analogues such as adenosine 5′-phosphosulfate. Nucleotides may include any suitable number of phosphates, e.g., three, four, five, six, or more than six phosphates.

As used herein, the term “polynucleotide” refers to a molecule that includes a sequence of nucleotides that are bonded to one another. A polynucleotide is one nonlimiting example of a polymer. Examples of polynucleotides include deoxyribonucleic acid (DNA), ribonucleic acid (RNA), and analogues thereof. A polynucleotide may be a single stranded sequence of nucleotides, such as RNA or single stranded DNA, a double stranded sequence of nucleotides, such as double stranded DNA, or may include a mixture of a single stranded and double stranded sequences of nucleotides. Double stranded DNA (dsDNA) includes genomic DNA, and PCR and amplification products. Single stranded DNA (ssDNA) can be converted to dsDNA and vice-versa. Polynucleotides may include non-naturally occurring DNA, such as enantiomeric DNA. The precise sequence of nucleotides in a polynucleotide may be known or unknown. The following are examples of polynucleotides: a gene or gene fragment (for example, a probe, primer, expressed sequence tag (EST) or serial analysis of gene expression (SAGE) tag), genomic DNA, genomic DNA fragment, exon, intron, messenger RNA (mRNA), transfer RNA, ribosomal RNA, ribozyme, cDNA, recombinant polynucleotide, synthetic polynucleotide, branched polynucleotide, plasmid, vector, isolated DNA of any sequence, isolated RNA of any sequence, nucleic acid probe, primer or amplified copy of any of the foregoing.

As used herein, a “polymerase” is intended to mean an enzyme having an active site that assembles polynucleotides by polymerizing nucleotides into polynucleotides. A polymerase can bind a primed single stranded target polynucleotide, and can sequentially add nucleotides to the growing primer to form a “complementary copy” polynucleotide having a sequence that is complementary to that of the target polynucleotide. Another polymerase, or the same polymerase, then can form a copy of the target nucleotide by forming a complementary copy of that complementary copy polynucleotide. Any of such copies may be referred to herein as “amplicons.” DNA polymerases may bind to the target polynucleotide and then move down the target polynucleotide sequentially adding nucleotides to the free hydroxyl group at the 3′ end of a growing polynucleotide strand (growing amplicon). DNA polymerases may synthesize complementary DNA molecules from DNA templates and RNA polymerases may synthesize RNA molecules from DNA templates (transcription). Polymerases may use a short RNA or DNA strand (primer), to begin strand growth. Some polymerases may displace the strand upstream of the site where they are adding bases to a chain. Such polymerases may be said to be strand displacing, meaning they have an activity that removes a complementary strand from a template strand being read by the polymerase. Exemplary polymerases having strand displacing activity include, without limitation, the large fragment of Bst (Bacillus stearothermophilus) polymerase, exo-Klenow polymerase or sequencing grade T7 exo-polymerase. Some polymerases degrade the strand in front of them, effectively replacing it with the growing chain behind (5′ exonuclease activity). Some polymerases have an activity that degrades the strand behind them (3′ exonuclease activity). Some useful polymerases have been modified, either by mutation or otherwise, to reduce or eliminate 3′ and/or 5′ exonuclease activity.

As used herein, the term “primer” is defined as a polynucleotide to which nucleotides may be added via a free 3′ OH group. A primer may include a 3′ block preventing polymerization until the block is removed. A primer may include a modification at the 5′ terminus to allow a coupling reaction or to couple the primer to another moiety. A primer may include one or more moieties which may be cleaved under suitable conditions, such as UV light, chemistry, enzyme, or the like. The primer length may be any suitable number of bases long and may include any suitable combination of natural and non-natural nucleotides. A target polynucleotide may include an “adapter” that hybridizes to (has a sequence that is complementary to) a primer, and may be amplified so as to generate a complementary copy polynucleotide by adding nucleotides to the free 3′ OH group of the primer.

A “capture primer” is intended to mean a primer that is coupled to the substrate and may hybridize to an adapter of the target polynucleotide. In some cases, a capture primer that is coupled to the substrate and may hybridize to another adapter of that target polynucleotide may be referred to as an “orthogonal capture primer.” The adapters may have respective sequences that are complementary to those of capture primers to which they may hybridize. A capture primer and an orthogonal capture primer may have different and independent sequences than one another. A capture primer that may be used to hybridize to an adapter of a target polynucleotide in order to couple that polynucleotide to the substrate, but that may not be used to grow a complementary strand during an amplification process, may in some cases be referred to as a “seeding primer.” A capture primer that may be used to grow a complementary strand during an amplification process may in some cases be referred to as an “amplification primer.”

As used herein, the term “substrate” refers to a material used as a support for compositions described herein. Example substrate materials may include glass, silica, plastic, quartz, metal, metal oxide, organo-silicate (e.g., polyhedral organic silsesquioxanes (POSS)), polyacrylates, tantalum oxide, complementary metal oxide semiconductor (CMOS), or combinations thereof. An example of POSS can be that described in Kehagias et al., Microelectronic Engineering 86 (2009), pp. 776-778, which is incorporated by reference in its entirety. In some examples, substrates used in the present application include silica-based substrates, such as glass, fused silica, or other silica-containing material. In some examples, substrates may include silicon, silicon nitride, or silicone hydride. In some examples, substrates used in the present application include plastic materials or components such as polyethylene, polystyrene, poly (vinyl chloride), polypropylene, nylons, polyesters, polycarbonates, and poly (methyl methacrylate). Example plastics materials include poly (methyl methacrylate), polystyrene, and cyclic olefin polymer substrates. In some examples, the substrate is or includes a silica-based material or plastic material or a combination thereof. In particular examples, the substrate has at least one surface comprising glass or a silicon-based polymer. In some examples, the substrates may include a metal. In some such examples, the metal is gold. In some examples, the substrate has at least one surface comprising a metal oxide. In one example, the surface comprises a tantalum oxide or tin oxide. Acrylamides, enones, or acrylates may also be utilized as a substrate material or component. Other substrate materials may include, but are not limited to gallium arsenide, indium phosphide, aluminum, ceramics, polyimide, quartz, resins, polymers and copolymers. In some examples, the substrate and/or the substrate surface may be, or include, quartz. In some other examples, the substrate and/or the substrate surface may be, or include, semiconductor, such as GaAs or ITO. The foregoing lists are intended to be illustrative of, but not limiting to the present application. Substrates may comprise a single material or a plurality of different materials. Substrates may be composites or laminates. In some examples, the substrate comprises an organo-silicate material. Substrates may be flat, round, spherical, rod-shaped, or any other suitable shape. Substrates may be rigid or flexible. In some examples, a substrate is a bead or a flow cell.

In some examples, a substrate includes a patterned surface. A “patterned surface” refers to an arrangement of different regions in or on an exposed layer of a substrate. For example, one or more of the regions may be features where one or more capture primers are present. The features can be separated by interstitial regions where capture primers are not present. In some examples, the pattern may be an x-y format of features that are in rows and columns. In some examples, the pattern may be a repeating arrangement of features and/or interstitial regions. In some examples, the pattern may be a random arrangement of features and/or interstitial regions. In some examples, substrate includes an array of wells (depressions) in a surface. The wells may be provided by substantially vertical sidewalls. Wells may be fabricated as is generally known in the art using a variety of techniques, including, but not limited to, photolithography, stamping techniques, molding techniques and microetching techniques. As will be appreciated by those in the art, the technique used will depend on the composition and shape of the array substrate.

The features in a patterned surface of a substrate may include wells in an array of features (e.g., microwells or nanowells) on glass, silicon, plastic or other suitable material(s) with a patterned, covalently-linked hydrogel such as poly (N-(5-azidoacetamidylpentyl) acrylamide-co-acrylamide) (PAZAM). The process creates hydrogel regions used for sequencing that may be stable over sequencing runs with a large number of cycles. The covalent linking of the hydrogel to the wells may be helpful for maintaining the hydrogel in the structured features throughout the lifetime of the structured substrate during a variety of uses. However in many examples, the hydrogel need not be fully or even partially covalently linked to the wells. For example, in some conditions silane free acrylamide (SFA) may be used as the hydrogel material.

In particular examples, a structured substrate may be made by patterning a suitable material with wells (e.g. microwells or nanowells), coating the patterned material with a hydrogel material (e.g., PAZAM, SFA or chemically modified variant thereof, such as the azidolyzed version of SFA (azido-SFA)) and polishing the surface of the hydrogel coated material, for example via chemical or mechanical polishing, thereby retaining hydrogel in the wells but removing or inactivating substantially all of the hydrogel from the interstitial regions on the surface of the structured substrate between the wells. Primers may be attached to hydrogel material. A solution including a plurality of target polynucleotides (e.g., a fragmented human genome or portion thereof) may then be contacted with the polished substrate such that individual target polynucleotides will seed individual wells via interactions with primers attached to the hydrogel material; however, the target polynucleotides will not occupy the interstitial regions due to absence or inactivity of the hydrogel material. Amplification of the target polynucleotides may be confined to the wells because absence or inactivity of hydrogel in the interstitial regions may inhibit outward migration of the growing cluster. The process is conveniently manufacturable, being scalable and utilizing conventional micro- or nano-fabrication methods.

A patterned substrate may include, for example, wells etched into a slide or chip. The pattern of the etchings and geometry of the wells may take on a variety of different shapes and sizes, and such features may be physically or functionally separable from each other. Particularly useful substrates having such structural features include patterned substrates that may select the size of solid particles such as microspheres. An exemplary patterned substrate having these characteristics is the etched substrate used in connection with BEAD ARRAY technology (Illumina, Inc., San Diego, Calif.).

In some examples, a substrate described herein forms at least part of a flow cell or is located in or coupled to a flow cell. Flow cells may include a flow chamber that is divided into a plurality of lanes or a plurality of sectors. Example flow cells and substrates for manufacture of flow cells that may be used in methods and compositions set forth herein include, but are not limited to, those commercially available from Illumina, Inc. (San Diego, CA).

As used herein, a “hydrogel” refers to a three-dimensional polymer network structure that includes polymer chains and is at least partially hydrophilic and contains water within spaces between the polymer chains. A hydrogel may include any suitable combination of hydrophilic, hydrophobic, and/or amphiphilic polymer(s), so long as the overall polymer network is hydrophilic and contains water within spaces between the polymer chains. Hydrogels include chemical hydrogels in which both the bonding to form the polymer chains, and any cross-linking between the polymer chains, is covalent; such cross-linking during hydrogel formation may be irreversible, as distinguished from the present reversible cross-linking which is performed after the hydrogel is formed. In some cases, the chemical hydrogel may include, or may consist essentially of, brush-like structures of polymer chains attached to a surface, substantially without physical or covalent crosslinks between polymer chains, or alternatively polymer chains with multiple attachment points to a surface, resulting in loops, but also lacking interchain crosslinks. Hydrogels also include physical hydrogels in which the bonding to form the polymer chains, and any cross-linking within the polymer chains, is not covalent. Nonlimiting examples of physical hydrogels include agarose and alginate.

As used herein, the “polymer chain” of a hydrogel is intended to mean those portions of the hydrogel that are polymerized with one another during the polymerization process. Polymer chains may be cross-linked to form the hydrogel. For example, cross-linkers may be added during or after the polymerization process that forms the polymer chains. Additionally, or alternatively, in some examples the polymer chains may be deposited on a substrate surface that includes functional groups to which functional groups of the polymer chains become coupled. The polymer chains may be coupled to the surface, e.g., via reactions between the functional groups of the polymer chains and the functional groups at the surface, and such coupling may cross-link the polymer chains to form the hydrogel. Such cross-linking may cause the polymer chains to covalently or non-covalently attach to one another, or may occur as a result of chain entanglement during polymerization and/or attachment to a surface.

As used herein, the term “directly” when used in reference to a layer covering the surface of a substrate is intended to mean that the layer covers the substrate's surface without a significant intermediate layer, such as, e.g., an adhesive layer or a polymer layer. Layers directly covering a surface may be attached to this surface through any chemical or physical interaction, including covalent bonds or non-covalent adhesion.

As used herein, the term “immobilized” when used in reference to a polynucleotide is intended to mean direct or indirect attachment to a substrate via covalent or non-covalent bond(s). In certain examples, covalent attachment may be used, or any other suitable attachment in which the polynucleotides remain stationary or attached to a substrate under conditions in which it is intended to use the substrate, for example, in polynucleotide amplification or sequencing. Polynucleotides to be used as capture primers or as target polynucleotides may be immobilized such that a 3′-end is available for enzymatic extension and at least a portion of the sequence is capable of hybridizing to a complementary sequence. Immobilization may occur via hybridization to a surface attached oligonucleotide, in which case the immobilized oligonucleotide or polynucleotide may be in the 3′-5′ orientation. Alternatively, immobilization may occur by means other than base-pairing hybridization, such as covalent attachment.

As used herein, the term “array” refers to a population of substrate regions that may be differentiated from each other according to relative location. Different molecules (such as polynucleotides) that are at different regions of an array may be differentiated from each other according to the locations of the regions in the array. An individual region of an array may include one or more molecules of a particular type. For example, a substrate region may include a single target polynucleotide having a particular sequence, or a substrate region may include several polynucleotides having the same sequence (or complementary sequences thereof). The regions of an array respectively may include different features than one another on the same substrate. Exemplary features include without limitation, wells in a substrate, beads (or other particles) in or on a substrate, projections from a substrate, ridges on a substrate or channels in a substrate. The regions of an array respectively may include different regions on different substrates than each other. Different molecules attached to separate substrates may be identified according to the locations of the substrates on a surface to which the substrates are associated or according to the locations of the substrates in a liquid or hydrogel. Exemplary arrays in which separate substrates are located on a surface include, without limitation, those having beads in wells.

As used herein, the term “plurality” is intended to mean a population of two or more different members. Pluralities may range in size from small, medium, large, to very large. The size of small plurality may range, for example, from a few members to tens of members. Medium sized pluralities may range, for example, from tens of members to about 100 members or hundreds of members. Large pluralities may range, for example, from about hundreds of members to about 1000 members, to thousands of members and up to tens of thousands of members. Very large pluralities may range, for example, from tens of thousands of members to about hundreds of thousands, a million, millions, tens of millions and up to or greater than hundreds of millions of members. Therefore, a plurality may range in size from two to well over one hundred million members as well as all sizes, as measured by the number of members, in between and greater than the above exemplary ranges. Exemplary polynucleotide pluralities include, for example, populations of about 1×10⁵ or more, 5×10⁵ or more, or 1×10⁶ or more different polynucleotides. Accordingly, the definition of the term is intended to include all integer values greater than two. An upper limit of a plurality may be set, for example, by the theoretical diversity of polynucleotide sequences in a sample.

As used herein, the term “double-stranded,” when used in reference to a polynucleotide, is intended to mean that all or substantially all of the nucleotides in the polynucleotide are hydrogen bonded to respective nucleotides in a complementary polynucleotide. A “partially” double stranded polynucleotide may have at least about 10%, at least about 25%, at least about 50%, at least about 60%, at least about 70%, at least about 80%, at least about 90% or at least about 95% of its nucleotides, but fewer than all of its nucleotides, hydrogen bonded to nucleotides in a complementary polynucleotide.

As used herein, the term “single-stranded,” when used in reference to a polynucleotide, means that essentially none of the nucleotides in the polynucleotide are hydrogen bonded to a respective nucleotide in a complementary polynucleotide. A polynucleotide that has an “inability” to hybridize to another polynucleotide may be single-stranded.

As used herein, the term “target polynucleotide” is intended to mean a polynucleotide that is the object of an analysis or action. The analysis or action includes subjecting the polynucleotide to amplification, sequencing and/or other procedure. A target polynucleotide may include nucleotide sequences additional to a target sequence to be analyzed. For example, a target polynucleotide may include one or more adapters, including an adapter that functions as a primer binding site, that flank(s) a target polynucleotide sequence that is to be analyzed. A target polynucleotide hybridized to a capture primer may include nucleotides that extend beyond the 5′ or 3′ end of the capture oligonucleotide in such a way that not all of the target polynucleotide is amenable to extension. In particular examples, target polynucleotides may have different sequences than one another but may have first and second adapters that are the same as one another. The two adapters that may flank a particular target polynucleotide sequence may have the same sequence as one another, or complementary sequences to one another, or the two adapters may have different sequences. Thus, species in a plurality of target polynucleotides may include regions of known sequence that flank regions of unknown sequence that are to be evaluated by, for example, sequencing (e.g., SBS). In some examples, target polynucleotides carry an adapter at a single end, and such adapter may be located at either the 3′ end or the 5′ end the target polynucleotide. Target polynucleotides may be used without any adapter, in which case a primer binding sequence may come directly from a sequence found in the target polynucleotide.

The terms “polynucleotide” and “oligonucleotide” are used interchangeably herein. The different terms are not intended to denote any particular difference in size, sequence, or other property unless specifically indicated otherwise. For clarity of description the terms may be used to distinguish one species of polynucleotide from another when describing a particular method or composition that includes several polynucleotide species.

As used herein, the term “amplicon,” when used in reference to a polynucleotide, is intended to means a product of copying the polynucleotide, wherein the product has a nucleotide sequence that is substantially the same as, or is substantially complementary to, at least a portion of the nucleotide sequence of the polynucleotide. “Amplification” and “amplifying” refer to the process of making an amplicon of a polynucleotide. A first amplicon of a target polynucleotide may be a complementary copy. Additional amplicons are copies that are created, after generation of the first amplicon, from the target polynucleotide or from the first amplicon. A subsequent amplicon may have a sequence that is substantially complementary to the target polynucleotide or is substantially identical to the target polynucleotide. It will be understood that a small number of mutations (e.g., due to amplification artifacts) of a polynucleotide may occur when generating an amplicon of that polynucleotide.

A substrate region that includes substantially only amplicons of a given polynucleotide may be referred to as “monoclonal,” while a substrate region that includes amplicons of polynucleotides having different sequences than one another may be referred to as “polyclonal.” A substrate region that includes a sufficient number of amplicons of a given polynucleotide to be used to sequence that polynucleotide maybe referred to as “functionally monoclonal.” Illustratively a substrate region in which about 60% or greater of the amplicons are of a given polynucleotide may be considered to be “functionally monoclonal.” Additionally, or alternatively, a substrate region from which about 60% or more of a signal is from amplicons of a given polynucleotide may be considered to be “functionally monoclonal.” A polyclonal region of a substrate may include different subregions therein that respectively are monoclonal. Each such monoclonal region, whether within a larger polyclonal region or on its own, may correspond to a “cluster” generated from a “seed.” The “seed” may refer to a single target polynucleotide, while the “cluster” may refer to a collection of amplicons of that target polynucleotide.

Forming Structures with Walls and/or Recesses

Some examples herein relate to forming structures that may be used in sequencing operations. For example, the structures may include a material having a first recess and a second recess defined therein. The first recess may be separated from the second recess by a wall. In some examples, a first hydrogel may be disposed within the first recess; and a second hydrogel may be disposed within the second recess. While the structures formed may be used for sequencing operations, it will be appreciated that the structures are not so limited, and may be used in other operations instead. Furthermore, it will be appreciated that the present structures may be formed in any suitable manner, and are not limited to being formed in the manner which will now be described.

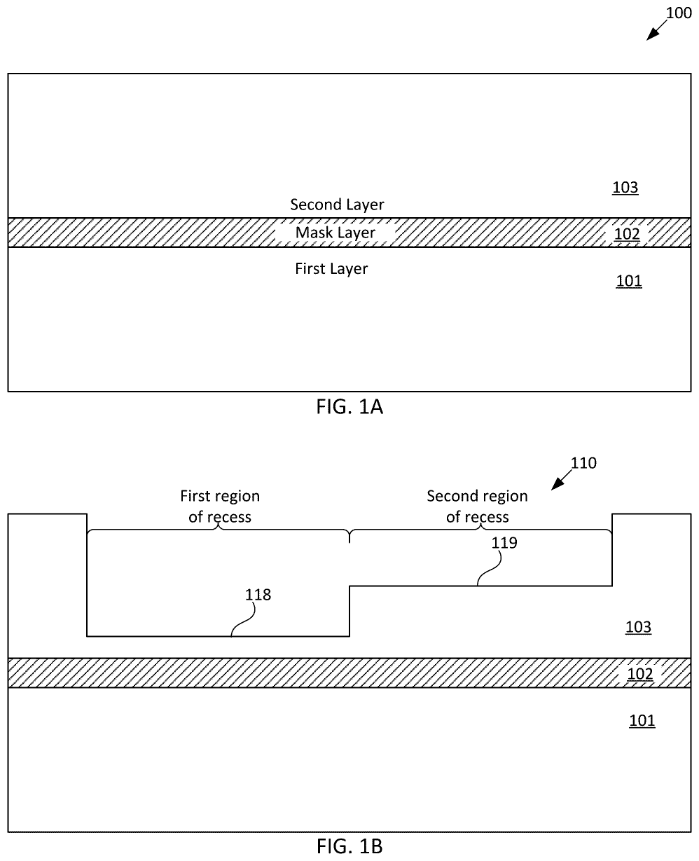

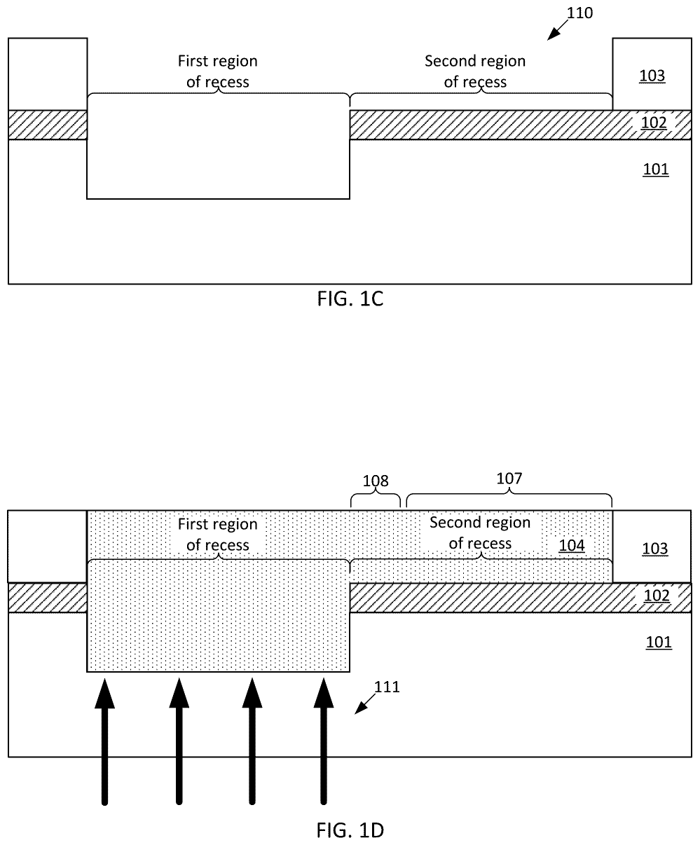

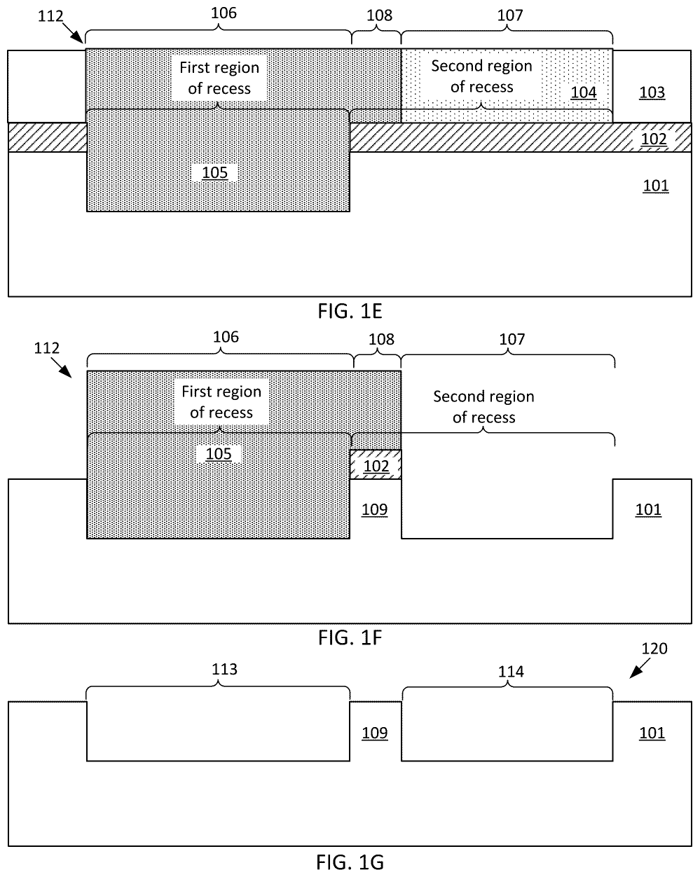

FIGS. 1A-1G schematically illustrate example operations for patterning, e.g., forming recesses in, a substrate 100. As illustrated in FIG. 1A, substrate 100 may include a first layer 101, a mask layer 102 disposed on the first layer, and second layer 103 disposed on the mask layer 102. As illustrated in FIG. 1B, a recess 110 may be formed in the second layer 103 of substrate 102. Recess 110 may be asymmetrical. For example, recess 110 may include a first region and a second region. As illustrated in FIG. 1B, a lower surface 118 of the first region may be deeper within the second layer than a lower surface 119 of the second region. Illustratively, recess 110 may be formed in the second layer 103 of the substrate 100 using nano-imprint lithography (NIL). For example, second layer 103 may include, or may essentially consist of, a resin, into which the recess is impressed. The resin may include a lift-off resist, e.g., such as polymethylglutaride-based resists which are commercially available from Kayaku Advanced Materials, Inc. Optionally, the material of first layer 101 (first material) also may include a resin. Alternatively, the material of first layer 101 may include a UV transparent material that can be etched in a similar manner as second layer 103, such as fused silica, tantalum pentoxide, or other transparent material. Mask 102 may include any suitable material that is optically opaque to wavelengths (such as UV light) that may be used to expose a photoresist in a manner such as described with reference to FIGS. 1D-1E, e.g., aluminum, copper, chromium, gold, or the like.

As illustrated in FIG. 1C, a first etching operation may be used to extend the first region of the recess 110 through the mask layer 102 and into the first layer 101 such that the lower surface of the first region is located within the first layer 101, and the lower surface of the second region of the recess is substantially located at the mask layer 102. In some examples, the first etching operation may include a first process that removes a portion of the second layer 103, a second process that removes a portion of the mask layer 102, and a third process that removes a portion of the first layer 101. In some examples, the first, second, and third processes may include respective dry etch operations. Dry etch operations for layers 101 and 103 may include, for example, use of a CF₄ plasma or a mixture of 90% CF₄ and 10% O₂ plasma. Dry etch operations for layer 102 may include, for example, use of a chlorine-based plasma (e.g., BCl₃ and Cl₂). Alternatively, layer 102 may be wet etched, for example with potassium hydroxide (KOH), tetramethylammonium hydroxide (TMAH), nitric acid, acetic acid, or phosphoric acid. When removed as a sacrificial layer, when layer 102 includes aluminum it may be removed in acidic or basic conditions; when layer 102 includes copper it may be removed using an iodine and iodide solution or FeCl₃; or when layer 102 includes gold it may be removed using an iodine and iodide solution.

A first pillar of photoresist then may be formed within the recess 110. For example, in a manner such as illustrated in FIG. 1D, photoresist precursor 104 may be disposed at least within the recess 110, and then exposed to light 111 in a region corresponding to the first region of the recess and a portion of the second region of the recess. Optionally, the photoresist precursor 104 may be exposed through the first layer 101 and through an aperture that the first etching operation forms through the mask layer 102, in an operation that may be referred to as “back-side exposure.” For example, as illustrated in FIG. 1D, the aperture through mask layer 102 corresponds to the first region of recess 110. Mask layer 102 may inhibit any direct exposure to light 111 of the photoresist precursor 104 in a first portion 107 of the second region of the recess, but may permit exposure to light 111 of the photoresist precursor 104 in a second portion 108 of the second region of the recess. For example, as illustrated in FIG. 1E, the photoresist precursor 104 in second portion 108 of the second region of the recess may be exposed via overexposure to light 111 through the aperture in the mask and thus form developed photoresist 105, while the photoresist precursor 104 in first portion 107 of the second region may not be exposed and thus may substantially remain undeveloped. The exposed photoresist 105 forms first pillar 112. First pillar 112 may have a first region 106 substantially filling the first region of the recess 110 and second region 108 partially extending into the second region of the recess.

As illustrated in FIG. 1F, photoresist precursor 104 in first portion 107 may be removed using a suitable remover, such as DMSO with sonication, acetone, or an NMP based stripper. A second etching operation then may be used to extend the first portion 107 of the second region of the recess through the mask layer 102 and into the first layer 101, such that a lower surface of the first portion 107 of the second region of the recess is located within the first layer 101. However, the first region 106 of the first pillar 112 inhibits etching of the first region of the recess, and the second region 108 of the first pillar 112 inhibits etching of the second portion of the second region of the recess so as to form a wall 109 located within the first layer 101 and between the first region of the recess 110 and the first portion 107 of the second region of the recess, as illustrated in FIG. 1F. In some examples, the second etching operation includes a first process that removes a portion of the mask layer 102, and a second process that removes a portion of the first layer 101. Unexposed portion(s) of the photoresist precursor 104 may be removed as part of one or more of such processes, or in a separate process.

In the nonlimiting example illustrated in FIG. 1G, pillar 112 may be removed, which also may remove the remaining piece of mask layer 102 which was under pillar 112, to provide structure 120 including substrate 101, first and second recesses 113, 114 disposed therein, and wall 109 between the first recess 113 and second recess 114. Wall 109 may have any suitable dimensions. In some examples, the wall 109 has a thickness of about 1 nm to about 400 nm between the first recess 113 (corresponding to the first region of the original recess 110) and the second recess 114 (corresponding to the first portion 107 of the second region of the original recess 110). Illustratively, the wall 109 may have a thickness of about 40 nm to about 300 nm between the first recess 113 (corresponding to the first region of the original recess 110) and the second recess 114 (corresponding to the first portion 107 of the second region of the original recess 110). For example, the wall 109 may have a thickness of about 100 nm to about 200 nm between the first recess 113 (corresponding to the first region of the original recess 110) and the second recess 114 (corresponding to the first portion 107 of the second region of the original recess 110). The thickness of wall 109 may be controlled, at least in part, by controlling the overexposure described with reference to FIGS. 1D and 1E. The recesses 113 and 114 may have any suitable dimensions. In some examples, recesses 113 and 114 are about the same size as one another. In other examples, recesses 113 and 114 are different sizes than one another.

In some examples, structure 120 of FIG. 1G may be used in sequencing operations, or any other suitable operations described or not specifically described herein. Moreover, any structures such as described with reference to FIGS. 1A-1G may be used in any other suitable operations. That is, structure 120 is just one example of a structure that can be used in any suitable practical application.

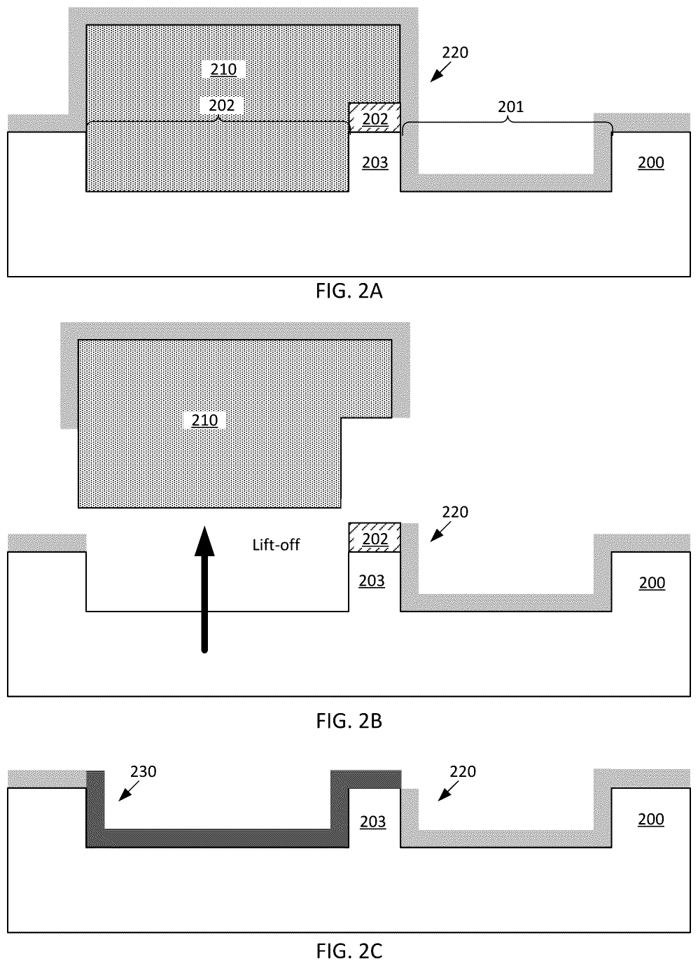

For example, FIGS. 2A-2C schematically illustrate additional example structures and operations for disposing different hydrogels in respective recesses in a substrate. As illustrated in FIG. 2A, beginning with a structure such as described with reference to FIG. 1F (which structure may be formed using operations such as described with reference to FIGS. 1A-1F, or any other suitable combination of operations), a first hydrogel 220 may be disposed within a first recess 201 of a substrate 200 and over a pillar 210. The substrate 200 may include a second recess 202 in which the pillar 210 is disposed, and a wall 203 separating the first recess from the second recess. Here and elsewhere herein, the designation “first” or “second” (or the like) is arbitrary. For example, first recess 201 illustrated in FIG. 2A may correspond to second recess 114 of FIG. 20G, and second recess 202 illustrated in FIG. 2A may correspond to first recess 113 of FIG. 20G. Substrate 200, recesses 201, 202, wall 203, and pillar 210 optionally may be configured in a manner such as described with reference to FIGS. 1A-1G, and optionally may be formed using operations such as described with reference to such figures. As such, FIG. 2A illustrates that a portion of pillar 202 and a portion of mask layer 202 are disposed over wall 203. However, it will be understood that a portion of pillar 202 need not necessarily be disposed over wall 203, and that mask layer 202 may not necessarily be present in all examples, e.g., in examples which are formed using different operations than those described above.

In a manner such as illustrated in FIG. 2B, while the first hydrogel 220 is disposed within the first recess 201, pillar 210 may be removed. Such a process may be referred to as “lift-off” because the pillar may be removed substantially intact from recess 202. Such lift-off may be performed using a suitable solvent or combination of solvents, such as a mixture of dimethyl sulfoxide (DMSO) and water (e.g., 90% DMSO in water); DMSO with sonication; or an N-methyl-2-pyrrolidone (NMP) based stripper. Any remaining mask layer 202 optionally may be removed using a suitable acid or base and/or buffer. As illustrated in FIG. 2C, after pillar 210 is removed and after remaining mask layer 202 optionally is removed, a second hydrogel 230 may be disposed within the second recess 202. Any suitable operations may be used to inhibit second hydrogel 230 from becoming disposed over first hydrogel 220. For example, deposition of second hydrogel 230 may be performed under high ionic strength (e.g., in the presence of 10×PBS, NaCl, KCl, or the like), such that the second hydrogel 230 substantially does not deposit on or adhere to the first hydrogel 220. As such, the bare portions illustrated in FIG. 2B selectively receive the second hydrogel 230. Additionally, or alternatively, the bare portions illustrated in FIG. 2B may be activated to generate surface groups that react with second hydrogel 230. Wall 203 may at least partially separate the first hydrogel 220 from the second hydrogel 230. In a manner such as illustrated in FIG. 2C, first hydrogel 220 may be disposed on sidewalls of recess 201, the sidewalls being formed at least by the substrate 200 and wall 203. Similarly, second hydrogel 230 may be disposed on sidewalls within recess 202, the sidewalls being formed at least by substrate and the wall 203.

The hydrogel 120 disposed as described with reference to FIG. 2A and the hydrogel disposed as described with reference to FIG. 2B respectively may include any suitable type of hydrogel (such as described elsewhere herein), and may be deposited in any suitable manner, such as by spin-coating, ink-jet (e.g., global precision dispense (GPD) using a GPD tool), spray, slot-die, dip-coating, dunk-coating, and the like. Optionally, substrate 200 may be pre-treated before disposing hydrogel 220, e.g., may be functionalized to include moieties that may react with corresponding moieties in hydrogel 220 so as to covalently couple hydrogel 220 to the substrate. Similarly, substrate 200 may be pre-treated after disposing hydrogel 220, and before disposing hydrogel 230 e.g., may be functionalized to include moieties that may react with corresponding moieties in hydrogel 230 so as to covalently couple hydrogel 230 to the substrate. Additionally, or alternatively, hydrogel 220 may be modified after being deposited and before hydrogel 230 is deposited, so as to inhibit chemical reactions between hydrogel 220 and hydrogel 230.

Hydrogels 220 and 230 optionally may be prepared for use in seeding operations, amplification operations, and/or sequencing operations, e.g., of a polynucleotide. For example, the first hydrogel 220 may be coupled to a first set of capture primers, and the second hydrogel 230 may be coupled to a second set of capture primers. Capture primers of the first set may be of a different type than capture primers of the second set. For example, the first set of capture primers may include seeding primers, and the second set of capture primers may include amplification primers, e.g., a mixture of different amplification primers. Or, for example, the first set of capture primers may include a first set of amplification primers and the second set of capture primers may include a second set of different amplification primers. The capture primers may be coupled to the respective hydrogels at any suitable time. For example, the first hydrogel 220 may be coupled to the first set of capture primers after removing the pillar 210 from the first recess 202 and before disposing the second hydrogel within the first portion of the second region of the recess. Additionally, or alternatively, the second hydrogel 230 may be coupled to the second set of capture primers after the second hydrogel is disposed within recess 202. In other examples, one of the first and second hydrogels 220, 230 is coupled to capture primers and the other of the first and second hydrogels is used to capture a particle, such as a hydrogel particle. In still other examples, neither of the first and second hydrogels 220, 230 is coupled to capture primers and instead are used to capture respective particles, e.g., hydrogel particles.

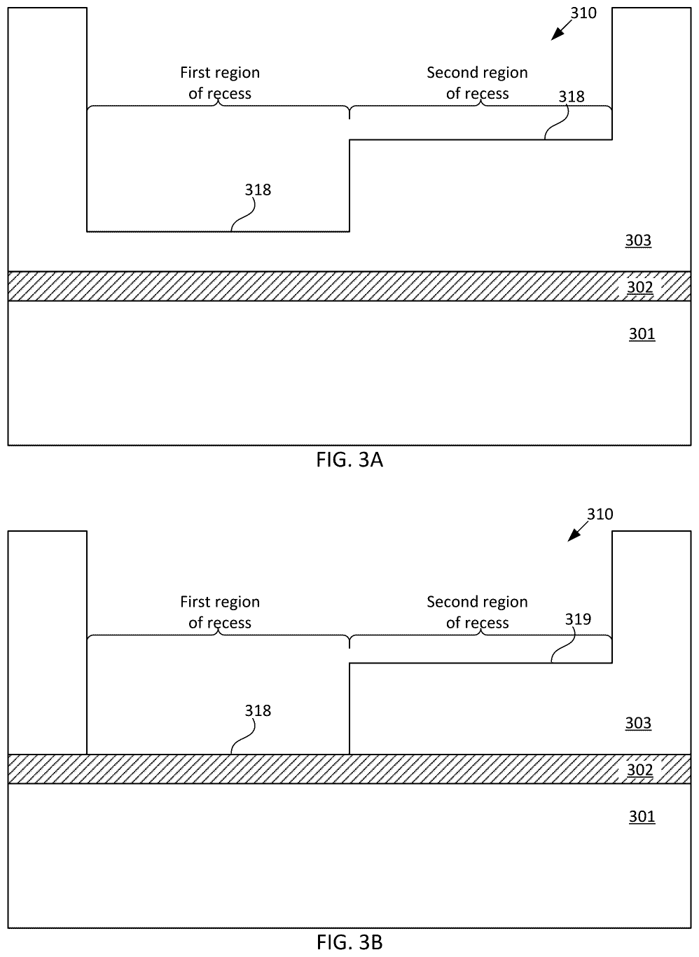

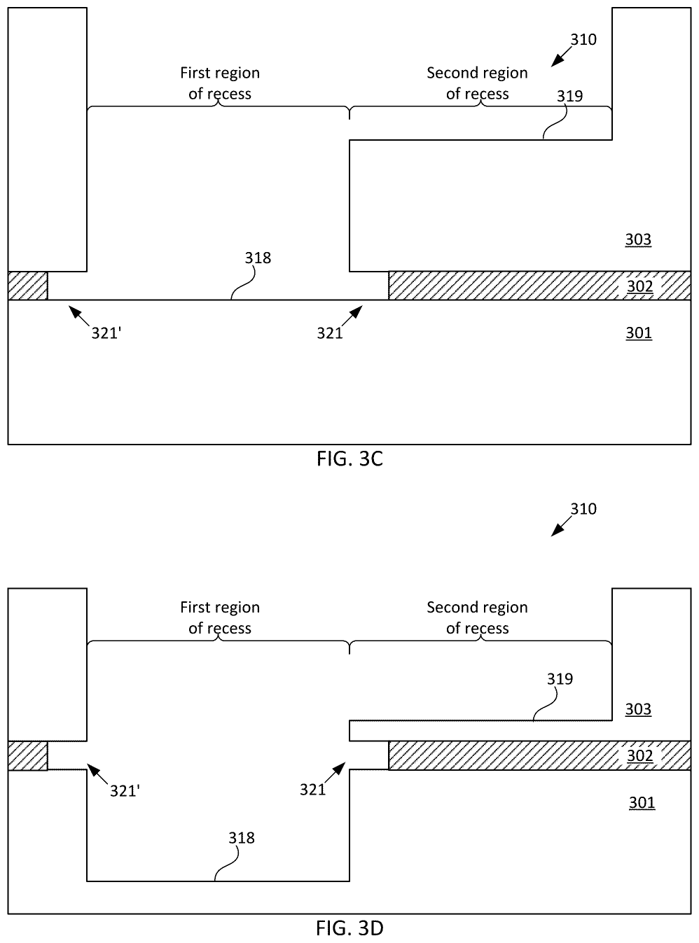

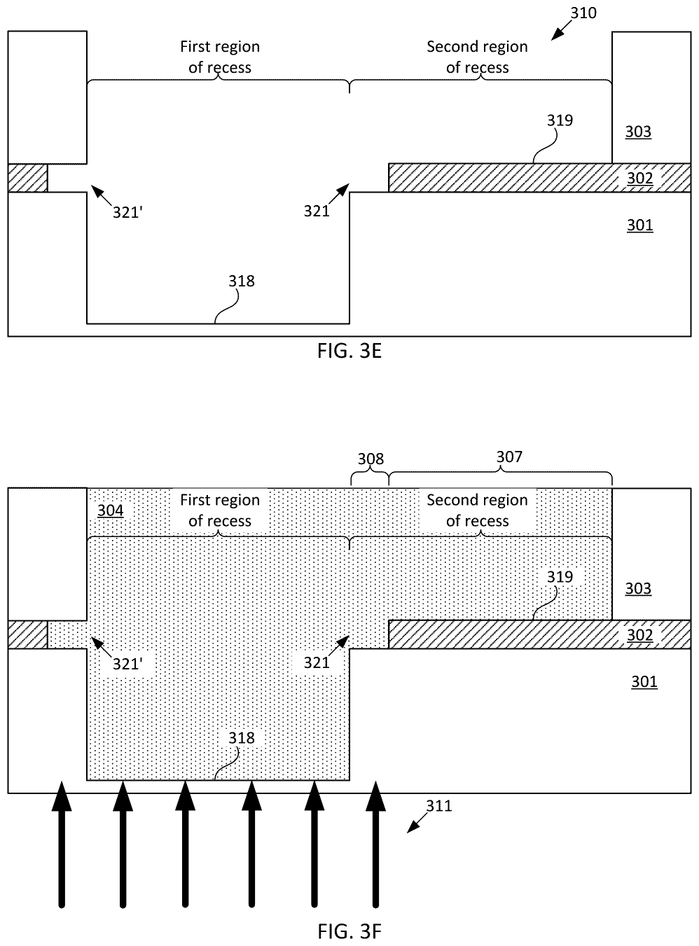

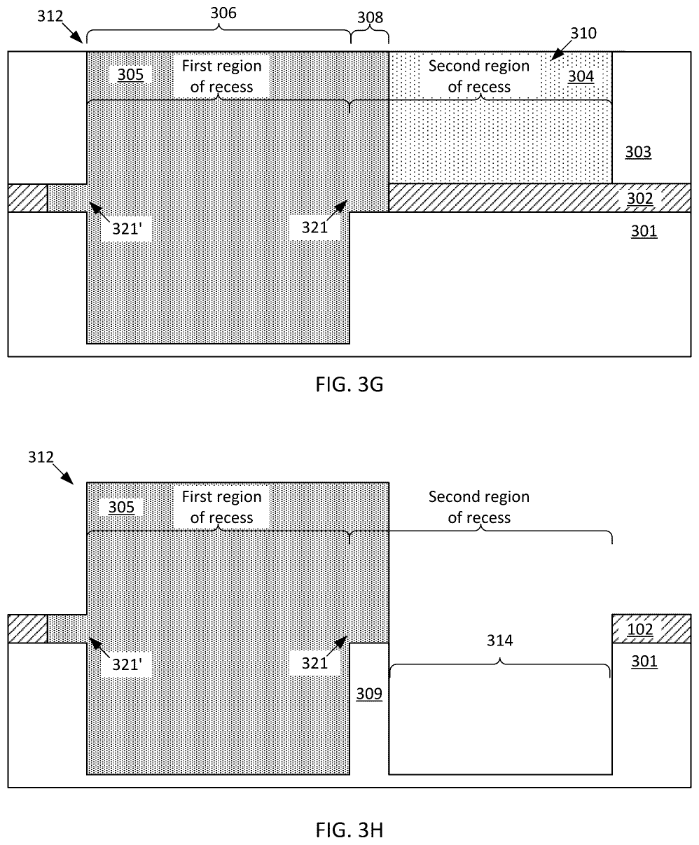

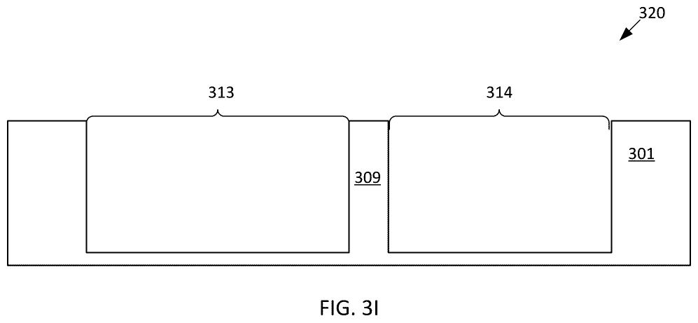

FIGS. 3A-3I schematically illustrate additional example operations for patterning, e.g., forming recesses in, a substrate. As illustrated in FIG. 3A, and similarly as described with reference to FIG. 1A, the substrate may include a first layer 301, a mask layer 302 disposed on the first layer, and second layer 303 disposed on the mask layer 302. Nonlimiting examples of materials suitable for use in first layer 301, mask layer 302, and second layer 303 are the same provided with reference to first layer 101, mask layer 102, and second layer 103 described with reference to FIG. 1A. As also illustrated in FIG. 3A, a recess 310 may be formed in the second layer 303 of the substrate. Recess 310 may be asymmetrical. For example, recess 310 may include a first region and a second region. As illustrated in FIG. 3A, and similarly as described with reference to FIG. 1B, a lower surface 318 of the first region may be deeper within the second layer than a lower surface 319 of the second region. Illustratively, recess 310 may be formed in the second layer 303 of the substrate using nano-imprint lithography (NIL).

As illustrated in FIG. 3B, a first etching operation may be used to extend the first region of the recess 310 to the mask layer 302, such that the lower surface of the first region is located approximately at the upper surface of mask layer 302, and the lower surface of the second region of the recess is located within second layer 303. As illustrated in FIG. 3C, the first etching operation also may be used to extend the first region of the recess 310 through the mask layer 302. As illustrated in FIG. 3D, the first etching operation also may be used to extend the first region of the recess 310 into the first layer 301, such that the lower surface of the first region is located within first layer 301, and the lower surface of the second region of the recess is located within second layer 303. As illustrated in FIG. 3E, the first etching operation also may be used to extend the first region of the recess 310 further into the first layer 301, such that the lower surface of the first region is located within first layer 301, and the lower surface of the second region of the recess is located at the upper surface of mask layer 302. In some examples, the process for layers 301 and 303 may include respective dry etch operations such as described above for layers 101 and 103. Layer 302 may be wet etched, for example using reagent(s) appropriate to the material used to form layer 302, some nonlimiting examples of which are provided above with reference to FIGS. 1A-1C. In this regard, note that the first etching operation may undercut portion(s) 321, 321′ of mask layer 302. One or more of such undercut portion(s) 321, 321′ may be used to form a wall between recesses, in a manner as will now be described.

A pillar of photoresist then may be formed within the recess 310, in a manner similar in some ways to that described with reference to FIG. 1D. For example, in a manner such as illustrated in FIG. 3F, photoresist precursor 304 may be disposed at least within the recess 310, and then exposed to light 311 in a region corresponding to the first region of the recess and a portion of the second region of the recess. More specifically, photoresist precursor may flow into undercut portions 321, 321′ and because the mask layer 302 has been removed from such portions, the photoresist precursor within these undercut portions also may be exposed to light. Undercut region 321 may correspond to a portion of the second region of recess 310. Optionally, the photoresist precursor 304 may be exposed through the first layer 301 and through an aperture that the first etching operation forms through the mask layer 302, using back-side exposure. For example, as illustrated in FIG. 3F, a portion of the aperture through mask layer 302 corresponds to the first region of recess 310. Mask layer 302 may inhibit any direct exposure to light 311 of the photoresist precursor 304 in a first portion 307 of the second region of the recess, but in undercut region 321 permits exposure to light 311 of the photoresist precursor 304 in a second portion 308 of the second region of the recess. Note, however, that while portion 108 described with reference to FIG. 1E was exposed via overexposure to light 111 through the aperture in the mask 105, in FIGS. 3F-3G overexposure is not needed to expose portion 308. Similarly as described with reference to FIG. 1E, exposed portions of photoresist precursor 304 form developed photoresist 305, while the photoresist precursor 304 in first portion 307 of the second region may not be exposed and thus may substantially remain undeveloped. The exposed photoresist 305 forms pillar 312 illustrated in FIG. 3G. Similarly as described with reference to FIG. 1E, pillar 312 may have a first region 306 substantially filling the first region of the recess 310 and second region 308 partially extending into the second region of the recess.

As illustrated in FIG. 3H, photoresist precursor 304 in first portion 307 may be removed using a suitable remover, such as DMSO with sonication, acetone, or an NMP based stripper. A second etching operation then may be used to extend the first portion 307 of the second region of the recess through the mask layer 302 and into the first layer 301, such that a lower surface of the first portion 307 of the second region of the recess is located within the first layer 301 as shown in FIG. 3H. However, the first region 306 of the pillar 312 inhibits etching of the first region of the recess, and the second region 308 of the pillar 312 inhibits etching of the second portion of the second region of the recess so as to form a wall 309 located within the first layer 301 and between the first region of the recess 310 and the first portion 307 of the second region of the recess, as illustrated in FIG. 3H. In some examples, the second etching operation includes a first process that removes a portion of the mask layer 302, and a second process that removes a portion of the first layer 301. Unexposed portion(s) of the photoresist precursor 304 may be removed as part of one or more of such processes, or in a separate process.

In the nonlimiting example illustrated in FIG. 3I, pillar 312 may be removed, which also may remove the remaining piece of mask layer 302 which was under pillar 312, to provide structure 320 including substrate 301, first and second recesses 313, 314 disposed therein, and wall 309 between the first recess 313 and second recess 314. Wall 309 may have any suitable dimensions. In some examples, the wall 309 has a thickness of about 3 nm to about 400 nm between the first recess 313 (corresponding to the first region of the original recess 310) and the second recess 314 (corresponding to the first portion 307 of the second region of the original recess 310). Illustratively, the wall 309 may have a thickness of about 40 nm to about 300 nm between the first recess 313 (corresponding to the first region of the original recess 310) and the second recess 314 (corresponding to the first portion 307 of the second region of the original recess 310). For example, the wall 309 may have a thickness of about 300 nm to about 200 nm between the first recess 313 (corresponding to the first region of the original recess 310) and the second recess 314 (corresponding to the first portion 307 of the second region of the original recess 310). The thickness of wall 309 may be controlled, at least in part, by controlling the undercut of layer 302 described with reference to FIG. 3C. The recesses 313 and 314 may have any suitable dimensions. In some examples, recesses 313 and 314 are about the same size as one another. In other examples, recesses 313 and 314 are different sizes than one another.

In some examples, structure 320 of FIG. 3G may be used in sequencing operations, or any other suitable operations described or not specifically described herein. Moreover, any structures such as described with reference to FIGS. 3A-3G may be used in any other suitable operations. That is, structure 320 is just one example of a structure that can be used in any suitable practical application.

Illustratively, first and second hydrogels respectively may be disposed in recesses 313 and 314 in a manner such as described with reference to FIGS. 2A-2C. For example, a first hydrogel may be disposed over the structure illustrated in FIG. 3H to dispose a hydrogel in recess 314, then pillar 312 may be removed, and then a different hydrogel may be disposed in recess 313.

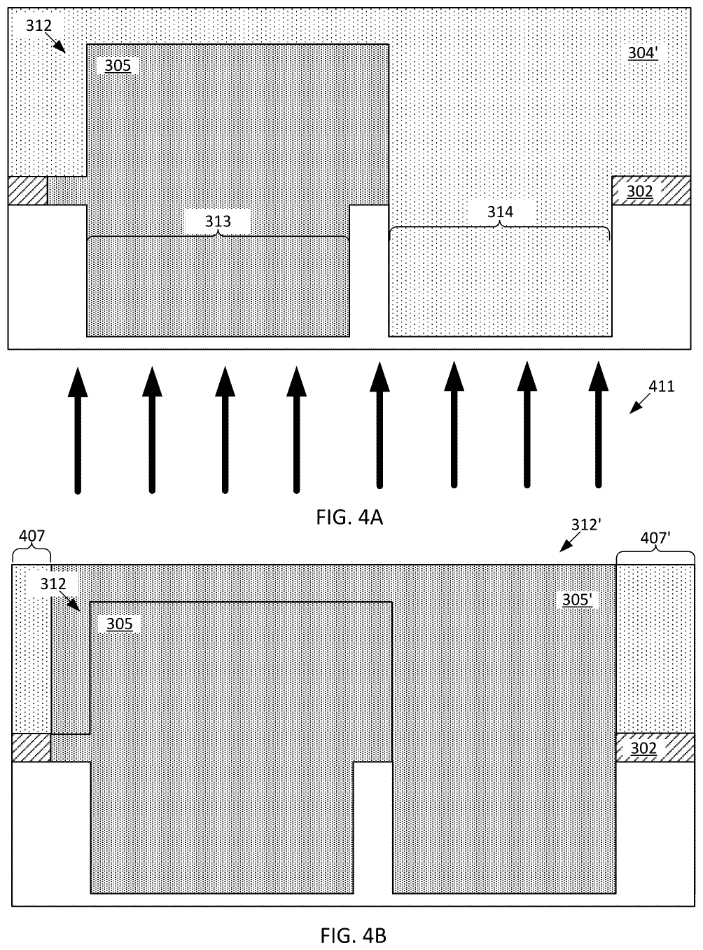

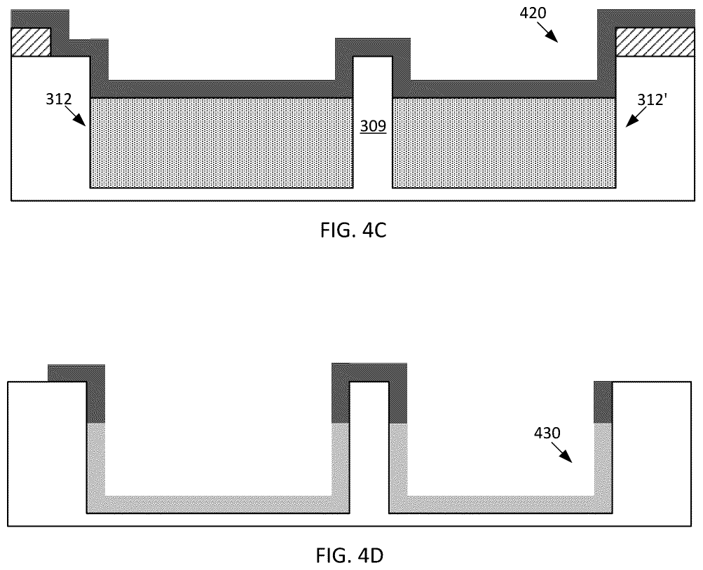

Alternatively, FIGS. 4A-4D schematically illustrate additional example structures and operations for disposing different hydrogels in respective recesses in a substrate. As illustrated in FIG. 4A, beginning with a structure such as described with reference to FIG. 3H (which structure may be formed using operations such as described with reference to FIGS. 3A-3G, or any other suitable combination of operations), additional photoresist precursor 304′may be disposed at least in recess 314, and optionally over pillar 312 as well. The photoresist precursor 304′ may be exposed through the first layer 301 and through an aperture that the first etching operation forms through the mask layer 302, using back-side exposure. For example, as illustrated in FIG. 4B, mask layer 302 may inhibit any direct exposure to light 311 of the photoresist precursor 304′ in regions 407, 407′ where the mask layer is located, but in regions without the mask layer light 411 may be used to expose the photoresist precursor 304 without the need for overexposure. Similarly as described with reference to FIG. 1E, exposed portions of photoresist precursor 304′ form developed photoresist 305′, while the photoresist precursor 304 regions 407, 407′ not be exposed and thus may substantially remain undeveloped. The exposed photoresist 305′ forms second pillar 312′ illustrated in FIG. 3G. In examples where the same type of photoresist precursor is used to form pillar 312 and second pillar 312′, the resulting structure may be considered to include just one pillar which substantially fills both of recesses 313 and 314.

In a manner such as now will be described, different hydrogels may be applied to different portions of the substrate. For example, as shown in FIG. 4C, a selective photoresist timed dry etch may be used to reduce the height of pillars 312, 312′ such that a portion of wall 309, and portions of the sidewalls of recesses 313, 314 are exposed. As also shown in FIG. 4C, after such an etch, a first hydrogel 420 may be disposed over the exposed portions of the wall 309, exposed portions of the sidewalls of recesses 313, 314, and over the remaining portions of pillars 312, 312′. In a manner such as illustrated in FIG. 4D, while the first hydrogel 420 is disposed on the portions of the wall and portions of recesses 313, 314, pillars 312, 312′ may be removed in a lift-off process. Any remaining mask layer 202 optionally may be removed using a suitable acid or base and/or buffer. As also illustrated in FIG. 4D, after pillar 312, 312′ are removed and after remaining mask layer 302 optionally is removed, a second hydrogel 430 may be disposed on exposed portions of recesses 313, 314. Any suitable operations may be used to inhibit second hydrogel 430 from becoming disposed over first hydrogel 420, e.g., such as described with reference to FIGS. 2A-2C. Wall 203 may at least partially separate the hydrogel 430 within recess 313 from the hydrogel within recess 314. The hydrogels 420, 430 respectively may include any suitable type of hydrogel (such as described elsewhere herein), and may be deposited in any suitable manner, such as described elsewhere herein. Optionally, the substrate may be pre-treated before disposing hydrogel 420 and/or hydrogel 430, in a manner such as described elsewhere herein. Additionally, or alternatively, hydrogels 420 and/or 430 may be modified after being deposited and before hydrogel 230 is deposited, so as to inhibit chemical reactions between hydrogel 220 and hydrogel 230.

Hydrogels 420 and 430 optionally may be prepared for use in seeding operations, amplification operations, and/or sequencing operations, e.g., of a polynucleotide. For example, the first hydrogel 420 may be coupled to a first set of capture primers, and the second hydrogel 430 may be coupled to a second set of capture primers. Capture primers of the first set may be of a different type than capture primers of the second set. For example, the first set of capture primers may include seeding primers, and the second set of capture primers may include amplification primers, e.g., a mixture of different amplification primers. Or, for example, the first set of capture primers may include a first set of amplification primers and the second set of capture primers may include a second set of different amplification primers. The capture primers may be coupled to the respective hydrogels at any suitable time. For example, the hydrogel 420 may be coupled to the first set of capture primers before removing the pillars 312, 312′ from the first recess 202. Additionally, or alternatively, the hydrogel 430 may be coupled to the second set of capture primers after hydrogel 420 is disposed on the wall and sidewalls. In other examples, one of hydrogels 420, 430 is coupled to capture primers and the other of the hydrogels is used to capture a particle, such as a hydrogel particle. In still other examples, neither of the hydrogels 420, 430 is coupled to capture primers.

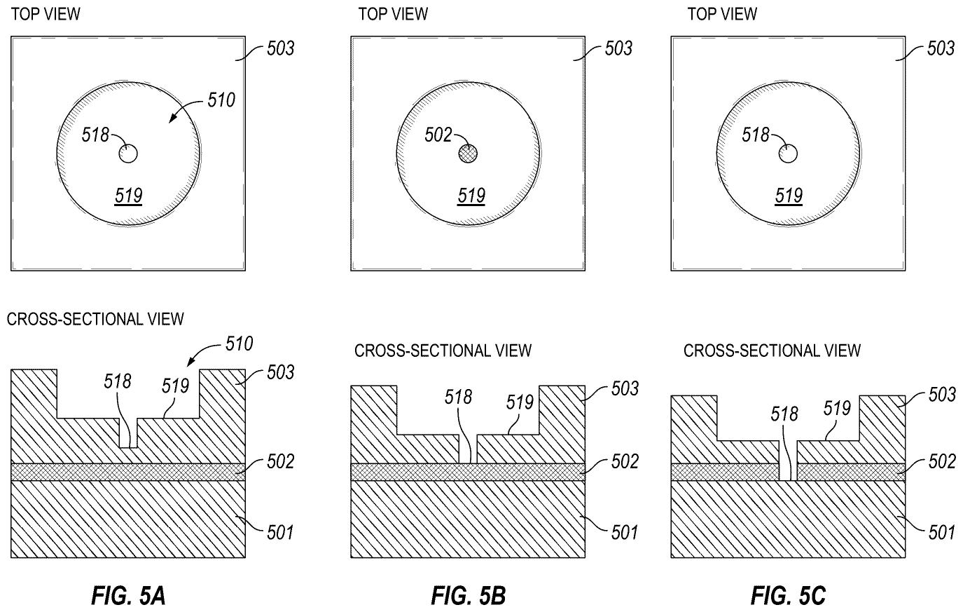

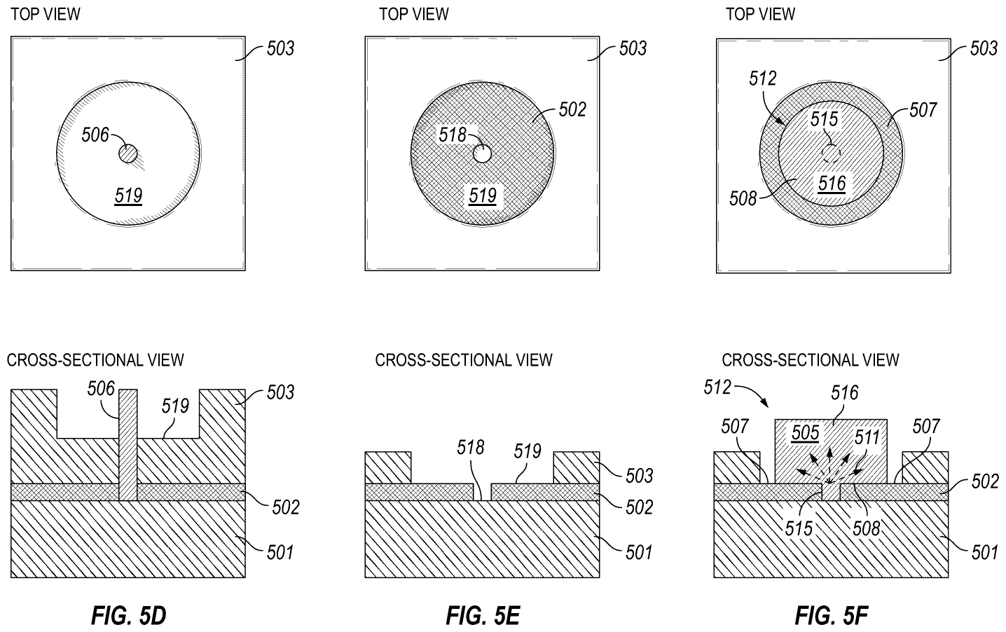

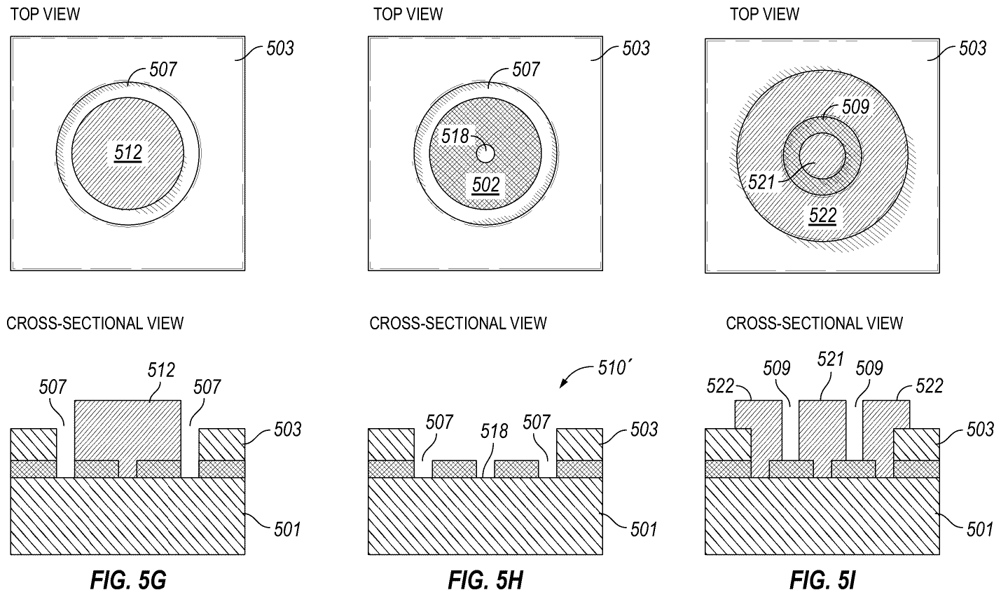

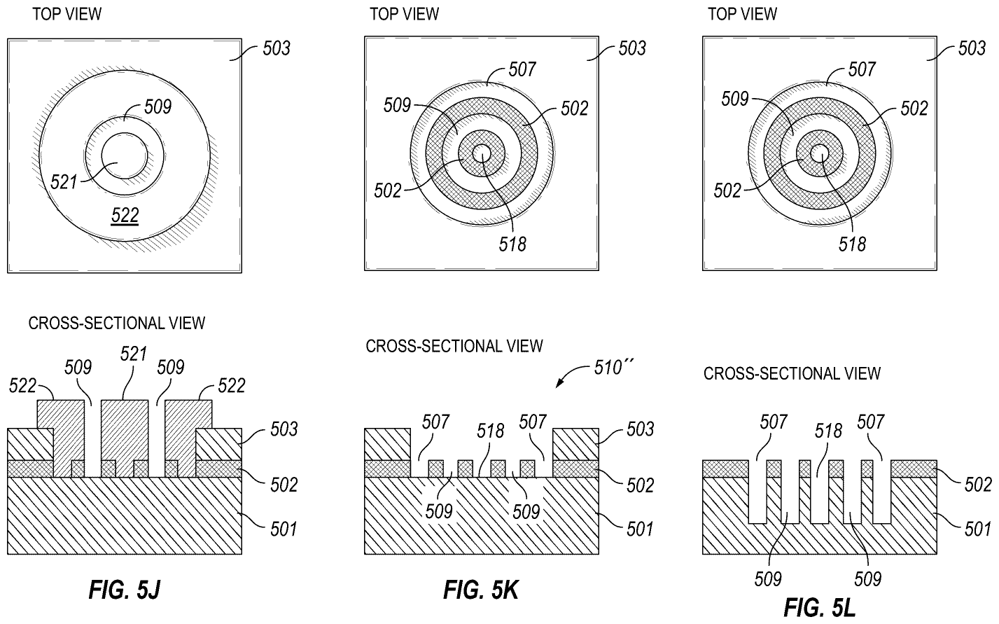

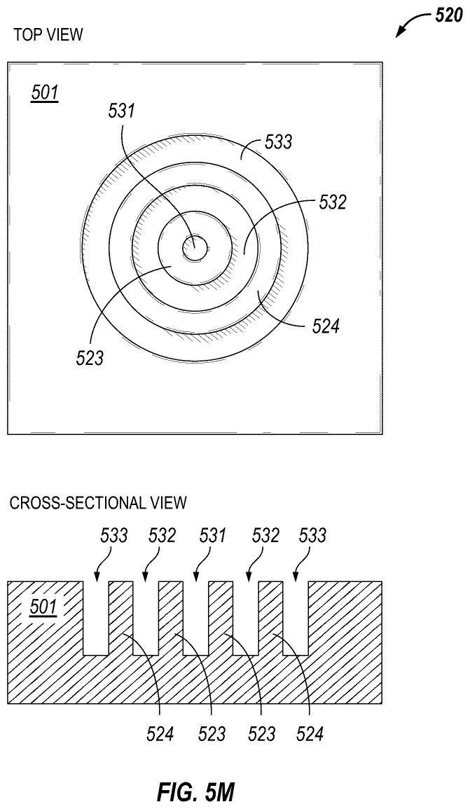

FIGS. 5A-5M schematically illustrate additional example structures and operations for forming recesses in a substrate 500. Within each of FIGS. 5A-5M, both a top view and a cross-sectional view are shown. As illustrated in FIG. 5A, and similarly as described with reference to FIG. 1A, the substrate may include a first layer 501, a mask layer 502 disposed on the first layer, and second layer 503 disposed on the mask layer 502. Nonlimiting examples of materials suitable for use in first layer 501, mask layer 502, and second layer 503 are the same provided with reference to first layer 101, mask layer 102, and second layer 103 described with reference to FIG. 1A. As also illustrated in FIG. 5A, a recess 510 may be formed in the second layer 503 of the substrate. Recess 510 may be symmetrical. For example, recess 510 may include a first region and a second region. As illustrated in FIG. 5A, and in some respects similarly as described with reference to FIG. 1B, a lower surface 518 of the first region may be deeper within the second layer than a lower surface 519 of the second region. However, in the example shown in FIG. 5A, recess 510 may be axially symmetric, with surface 518 forming the center of recess 510 and recess 519 surrounding surface 518. Illustratively, recess 510 may be formed in the second layer 503 of the substrate using nano-imprint lithography (NIL).

As illustrated in FIG. 5B, an etching operation may be used to extend the first region of the recess 510 to the mask layer 502, such that the lower surface 518 of the first region is located approximately at the upper surface of mask layer 502, and the lower surface 519 of the second region of the recess is located within second layer 503. As illustrated in FIG. 5C, an etching operation also may be used to extend the first region of the recess 510 through the mask layer 502. In some examples, the process for layer 501 may include a dry etch operation such as described above for layers 101 and 103. Layer 502 may be wet etched, for example using reagent(s) appropriate to the material used to form layer 502, some nonlimiting examples of which are provided above with reference to FIGS. 1A-1C. As illustrated in FIG. 5D, recess 510 may be filled with a photoresist which is backside exposed through the aperture in mask layer 502 to form a first pillar 506 which has approximately the same lateral dimension as the aperture, and any unexposed photoresist is removed. As illustrated in FIG. 5E, an etching operation may be used to remove a portion of second layer 503 while first pillar 506 protects first layer 501, and the first pillar 506 then may be removed. As such, the lower surface 518 of the first region of the recess remains located at the exposed top surface of first layer 501, and the lower surface 519 of the second region of the recess is located at the exposed top surface of second layer 502.

As illustrated in FIG. 5F, a pillar of photoresist then may be formed within the recess 510, in a manner similar in some ways to that described with reference to FIG. 1D and FIG. 3F. For example, a photoresist precursor may be disposed at least within the recess 510, and then exposed to light 511 in a region corresponding to the first region of the recess and a portion of the second region of the recess in a manner such as illustrated in FIG. 5F. More specifically, the photoresist precursor may be exposed through the first layer 501 and through an aperture that the earlier etching operation of FIG. 5B forms through the mask layer 502, using back-side overexposure. For example, as illustrated in FIG. 5F, the aperture through mask layer 502 corresponds to the first region of recess 510. Mask layer 502 may inhibit any direct exposure to light 511 of the photoresist precursor in a first portion 507 of the second region of the recess, but may permit exposure to light 511 of the photoresist precursor in a second portion 508 of the second region of the recess. For example, the photoresist precursor in second portion 508 of the second region of the recess may be exposed via overexposure to light 511 through the aperture in the mask and thus form developed photoresist 505, while the photoresist precursor in first portion 507 of the second region may not be exposed and thus may substantially remain undeveloped and then may be removed in a similar manner as described elsewhere herein. The exposed photoresist 505 forms second pillar 512. Second pillar 512 may have a first region 515 substantially filling the first region of the recess 510 and a second region 516 partially extending into the second region of the recess. As may be seen in the top view of FIG. 5F, the pillar 512 may be generally circular, and may be axially symmetric with first region 515 at its center. Region 507 may be generally annular.

An etching operation then may be used to extend the first portion 507 of the second region of the recess through the mask layer 502 while the second pillar 512 is in place, such that first portion 507 has a lower surface approximately at the upper surface of first layer 501, as illustrated in FIG. 5G. During such etching operation, patterned second layer 503 and second pillar 512 protect other portions of mask layer 502 from being etched. In the nonlimiting example illustrated in FIG. 5H, pillar 512 may be removed. The resulting structure includes recess 510′ including annular aperture 507 and central aperture at 518, both through mask layer 502 with the lower surfaces of such apertures being approximately at the upper surface of first layer 501.

As illustrated in FIG. 5I, additional pillars of photoresist then may be formed within the recess 510′, in a manner similar in some ways to that described with reference to FIG. 1D and FIG. 3F. For example, a photoresist precursor may be disposed at least within the recess 510′, and then exposed to light through the first layer 501 and through the apertures that the earlier etching operations of FIGS. 5B and 5G form through the mask layer 502, using back-side overexposure. Mask layer 502 may inhibit any direct exposure to light of the photoresist precursor in certain portions of the recess 510, but may permit exposure to light of the photoresist precursor in other portions of the recess which extend beyond the apertures formed through mask layer 502. For example, the photoresist precursor in portion 521 may be exposed via overexposure to light through the central aperture in the mask and thus form developed photoresist, and the photoresist precursor in portion 522 may be exposed via overexposure to light through the annular aperture in the mask and thus form developed photoresist, while the photoresist precursor in other regions may not be exposed and thus may substantially remain undeveloped and then may be removed in a similar manner as described elsewhere herein. The exposed photoresist forms a first, central pillar 521 and a second, annular pillar 522 which is separated from the first pillar by annular aperture 509. As may be seen in the top view of FIG. 51, the pillar 521 may be generally circular, and the pillar 522 may be generally annular.

An etching operation then may be used to extend annular aperture 509 through the mask layer 502 while pillars 521, 522 are in place, such that aperture 509 has a lower surface approximately at the upper surface of first layer 501, as illustrated in FIG. 5J. During such etching operation, patterned second layer 503 and pillars 521, 522 protect other portions of mask layer 502 from being etched. In the nonlimiting example illustrated in FIG. 5K, pillars 521, 522 may be removed. The resulting structure includes recess 510″ including annular aperture 507, annular aperture 509 within annular aperture 507, and central aperture at 518 within annular aperture 509, all through mask layer 502 with the lower surfaces of such apertures being approximately at the upper surface of first layer 501. As illustrated in FIG. 5L, apertures 507, 509, and 518 may be extended by etching exposed portions of first layer 501 through the apertures in mask layer 502.

As illustrated in FIG. 5M, the mask layer 502 optionally then may be removed to form structure 520 which includes a central recess 531, a first annular recess 532 which surrounds central recess 531 and is spaced apart from the central recess by first wall 523, and a second annular recess 533 which surrounds the first annular recess 532 and is spaced apart from the first annular recess by second wall 524. Wall 523 and 524, and recesses 531, 532, 533 may have any suitable dimensions. In some examples, wall 523 has a thickness of about 5 nm to about 400 nm between the central recess 531 and the first annular recess 532. Illustratively, the wall 523 may have a thickness of about 40 nm to about 500 nm, e.g., about 100 nm to about 200 nm. Additionally, or alternatively, in some examples, wall 524 has a thickness of about 5 nm to about 400 nm between the first annular recess 532 and the second annular recess 533. Illustratively, the wall 524 may have a thickness of about 40 nm to about 500 nm, e.g., about 100 nm to about 200 nm. The recesses 531, 532, 533 may have any suitable dimensions. In some examples, recesses 531, 532, 533 have about the same width as one another. In other examples, recesses 531, 532, 533 have different widths than one another.

In some examples, structure 520 of FIG. 5M may be used in sequencing operations, or any other suitable operations described or not specifically described herein. Moreover, any structures such as described with reference to FIGS. 5A-5M may be used in any other suitable operations. That is, structure 520 is just one example of a structure that can be used in any suitable practical application. Illustratively, first and second hydrogels respectively may be disposed in recesses 513 and 514 in a manner such as described with reference to FIGS. 2A-2C or 4A-4D.

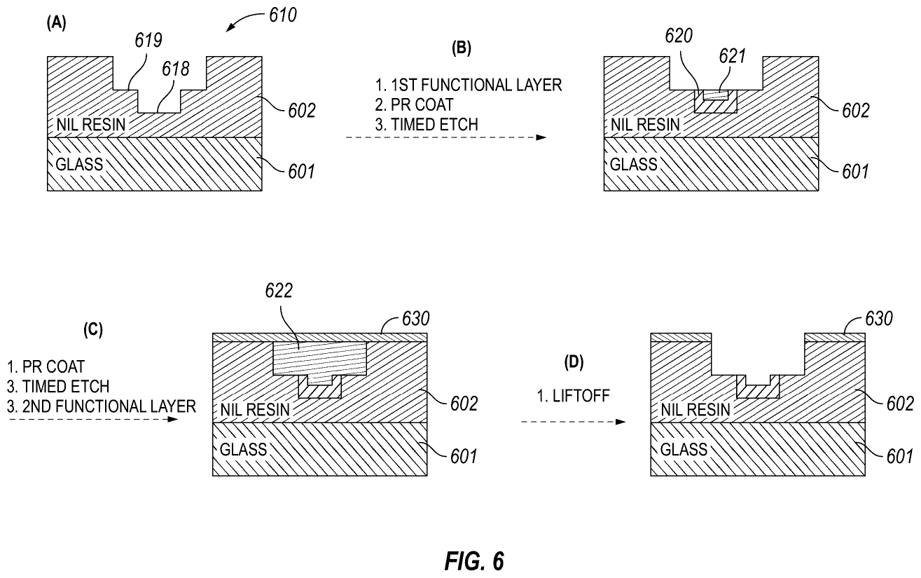

It should be appreciated that different hydrogels may be disposed on different respective regions of a substrate using methods other than those described with reference to FIGS. 2A-2C and 4A-4D. For example, FIG. 6 schematically illustrates additional example structures and operations for disposing different hydrogels on different regions of a substrate. In nonlimiting examples such as described with reference to FIG. 6, a first hydrogel is disposed within a first recess of a substrate; a pillar is disposed over the first hydrogel within the first recess of the substrate; a second hydrogel may be disposed over the pillar and over a portion of the substrate; and the pillar then removed.

More specifically, as shown in operation (A) of FIG. 6, recess 610 may be formed in second layer 602 (e.g., a resin) which may be disposed directly or indirectly on first layer 601 (e.g., glass). Recess 610 may be symmetrical. For example, recess 610 may include a first region and a second region. As illustrated in FIG. 6A, and in similarly as described with reference to FIG. 5A, a lower surface 618 of the first region may be deeper within the second layer than a lower surface 619 of the second region. Similarly as recess 510, recess 610 may be axially symmetric, with surface 618 forming the center of recess 610 and recess 619 surrounding surface 618. Illustratively, recess 610 may be formed in the second layer 602 of the substrate using nano-imprint lithography (NIL).

As illustrated at operation (B) of FIG. 6, a first functional layer 620 (such as a first hydrogel) may be disposed in recess 610. As also illustrated at operation (B) of FIG. 6, a pillar of photoresist (PR) then may be disposed in the recess and the portion within the center of the recess photolithographically exposed to form a pillar over the first functional layer disposed in the deeper portion of recess 610. As also illustrated at operation (B) of FIG. 6, a timed etch then may be performed to remove any photoresist or functional layer which is not located in the deeper portion of recess 610. Thus, the deeper portion of recess 610 includes the first functional layer which is protected by developed photoresist. As illustrated at operation (C) of FIG. 6, the size of the pillar may be increased by disposing additional photoresist (PR) 622 within the recess, and a timed etch performed to bring the top surface of the photoresist 622 approximately level with the top surface of second layer 602. As also illustrated at operation (C) of FIG. 6, a second functional layer 630 (such as a second hydrogel) may be disposed over the top surface of photoresist 622 and second layer 602. As illustrated in operation (D) of FIG. 6, a liftoff operation may be used to remove photoresist 622 and the portion of the second functional layer 630 disposed thereon, while leaving in place the portion of second functional layer 630 disposed on the upper surface of second layer 602, and also leaving in place the portion of first functional layer 620 which is disposed within recess 610. As such, as illustrated in FIG. 6D, first functional layer 620 (e.g., first hydrogel) may be disposed within recess 610, and second functional layer 630 (e.g., second hydrogel) may be disposed at a spaced distance from the first functional layer 620, e.g., on an upper surface of second layer 602.

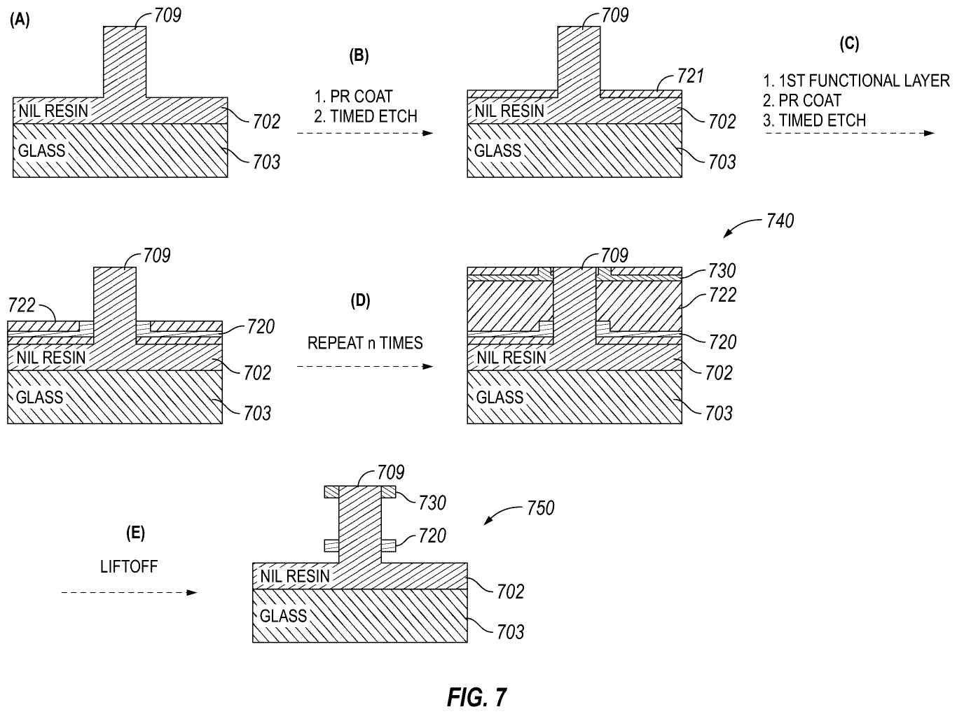

FIG. 7 schematically illustrates example structures and operations for disposing different hydrogels on different regions of a substrate. In the nonlimiting example shown in FIG. 7, at operation (A) a wall 709 is formed in a second layer 702 (e.g., a resin) which may be disposed directly or indirectly on first layer 701 (e.g., glass). At operation (B) of FIG. 7, a photoresist (PR) may be disposed over the second layer 702 (including wall 709) and then a timed etch performed to form a layer 721 of photoresist disposed on the horizontal portion of second layer 702 while leaving the vertical surfaces of wall 709 substantially exposed. At operation (C) of FIG. 7, a first functional layer 720 (e.g., a first hydrogel) is disposed on the layer 721 of photoresist and the exposed portion of wall 709. As illustrated in FIG. 7, the first hydrogel 720 optionally may have an “L” shape in examples where the surface energy of the resin forming wall 709 may be higher than the surface energy of the flat photoresist 721, causing the hydrogel 720 to preferentially gather at the corner between the photoresist and the wall.

Additional photoresist (PR) may be disposed over the first functional layer 720, and then a timed etch performed to form an additional layer 722 of photoresist disposed on the horizontal portion of first functional layer 720 while leaving the vertical surfaces of wall 709 substantially exposed. As shown at operation (D) of FIG. 7, the operations of disposing additional functional layer(s), disposing additional photoresist layer(s), and performing timed etches may be repeated any suitable number of times (n times). For example, as illustrated in FIG. 7, a structure 740 may be obtained that includes wall 709, a first functional layer 720 (e.g., first hydrogel) coupled to the wall, a third functional layer 730 (e.g., second hydrogel) coupled to the wall at a spaced distance from the first functional layer, and photoresist 722 disposed between the first and second functional layers 720, 730. As shown at operation (E) of FIG. 7, the photoresist may be removed in a liftoff operation which leaves residual portions of the first and second functional layers 720, 730 coupled to the wall 709 at a spaced distance from one another. For example, during the lift-off process, the photoresist may be removed by an organic solvent (such as 2-methoxy-1-methylethyl acetate (PGMEA)), while the functional layers 720, 730 substantially are not removed by the organic solvent. Additionally, molecular interactions between functional layer 720 and wall 709, and between functional layer 730 and wall 709 are sufficiently strong that portions of functional layers 720 and 730 remain coupled to the wall.

### Additional Comments

While various illustrative examples are described above, it will be apparent to one skilled in the art that various changes and modifications may be made therein without departing from the invention. The appended claims are intended to cover all such changes and modifications that fall within the true spirit and scope of the invention.

It is to be understood that any respective features/examples of each of the aspects of the disclosure as described herein may be implemented together in any appropriate combination, and that any features/examples from any one or more of these aspects may be implemented together with any of the features of the other aspect(s) as described herein in any appropriate combination to achieve the benefits as described herein.

1. A method, comprising:
disposing a first hydrogel within a first recess of a substrate and over a pillar, wherein the substrate comprises a second recess in which the pillar is disposed, and a wall separating the first recess from the second recess;
while the first hydrogel is disposed within the first recess, removing the pillar; and
after removing the pillar, disposing a second hydrogel within the second recess.

2. The method of claim 1, wherein the wall separates the first hydrogel from the second hydrogel.

3. The method of claim 1, wherein the first hydrogel is coupled to a first set of capture primers, and the second hydrogel is coupled to a second set of capture primers.

4. The method of claim 3, wherein capture primers of the first set are of a different type than capture primers of the second set.

5. The method of claim 3, wherein the first set of capture primers comprises seeding primers.

6. The method of claim 3, wherein the second set of capture primers comprises amplification primers.

7. The method of claim 3, wherein the first set of capture primers comprises a first set of amplification primers.

8. The method of claim 7, wherein the second set of capture primers comprises a second set of amplification primers.

9. The method of claim 3, comprising coupling the first hydrogel to the first set of capture primers after removing the pillar from the recess and before disposing the second hydrogel within the first portion of the second region of the recess.

10. The method of claim 9, wherein the second hydrogel is coupled to the second set of capture primers after the second hydrogel is disposed within the first portion of the second region of the recess.

11. The method of claim 1, wherein removing the pillar from the recess comprises a liftoff operation.

12. The method of claim 1, wherein the first hydrogel is disposed on sidewalls of the first region of the recess, the sidewalls being formed at least by the first layer and the wall.

13. The method of claim 12, wherein the second hydrogel is disposed on sidewalls within the first portion of the second region of the recess, the sidewalls being formed at least by the first layer and the wall.

14. A method of patterning a substrate comprising a first layer, a mask layer disposed on the first layer, and second layer disposed on the mask layer, the method comprising:
forming a recess in the second layer of substrate,
the recess comprising a first region and a second region, a lower surface of the first region being deeper within the second layer than a lower surface of the second region;
using a first etching operation to extend the first region of the recess through the mask layer and into the first layer such that the lower surface of the first region is located within the first layer, and the lower surface of the second region of the recess is substantially located at the mask layer;
forming a first pillar of photoresist within the recess,
the first pillar having a first region substantially filling the first region of the recess,
the first pillar having a second region partially extending into the second region of the recess;
using a second etching operation to extend a first portion of the second region of the recess through the mask layer and into the first layer such that a lower surface of the first portion of the second region of the recess is located within the first layer,
wherein the first region of the first pillar inhibits etching of the first region of the recess, and
wherein the second region of the first pillar inhibits etching of a second portion of the second region of the recess so as to form a wall located within the first layer and between the first region of the recess and the first portion of the second region of the recess.

15-47. (canceled)

48. A method, comprising:
disposing a first hydrogel within a recess of a substrate;
disposing a pillar over the first hydrogel within the recess of the substrate;
disposing a second hydrogel over the pillar and over a portion of the substrate; and
removing the pillar.

49-64. (canceled)
